(19) United States
(12) Patent Application Publication
(10) Pub. No.: US 2025/0233532 A1
(43) Pub. Date: Jul. 17, 2025

(54) CONTROL DEVICE FOR VIBRATION-TYPE ACTUATOR

(71) Applicant: CANON KABUSHIKI KAISHA, Tokyo (JP)

(72) Inventors: KENICHI KATAOKA, Kanagawa (JP); JUN SUMIOKA, Kanagawa (JP)

(21) Appl. No.: 19/010,763

(22) Filed: Jan. 6, 2025

(30) Foreign Application Priority Data
Jan. 15, 2024 (JP) 2024-004163

(51) Int. Cl. H02N 11/00; B81B 3/00; H03H 9/24

(52) U.S. Cl. CPC H02N 11/006; H03H 9/2431; B81B 3/0021

(57) ABSTRACT

To enable estimating thrust or speed of a vibration-type actuator without use of a thrust or speed detection sensor, a device is provided to control the vibration-type actuator, with a neural network that includes a plurality of input layers which receives at least a first input value and a second input value. The first input value is based on at least one of a phase difference between a first alternating-current signal and a second alternating-current signal, frequencies of the first alternating-current signal and the second alternating-current signal, and an amplitude of the first alternating-current signal or the second alternating-current signal. The second input value is at least one of a measured value of a vibrational state in a vibrating body and a measured value corresponding to an admittance characteristic of the vibrating body.

### BACKGROUND

### Field

The present disclosure generally relates to a control device for a vibration-type actuator.

### Related Art

Research performed for estimating the speed or position of a vibration-type actuator based on various state quantities of the vibration-type actuator using a neural network have been published, and sensorless control techniques which do not require a sensor for detecting the position or speed have been reported.

IEEE Ind. Appl. Conf. IAS 41, p. 2488, 2006, “Sensorless Speed Control of Traveling Wave Ultrasonic Motor” (hereinafter referred to as “Non-patent Literature 1”) discusses a technique which controls speeds by estimating the speed of a vibration-type actuator based on the frequency of a driving voltage, a current flowing through the vibration-type actuator, and a load torque of the vibration-type actuator using a neural network.

Journal of Power Electronics, Vol. 6, No. 1, January 2006, “Speed Sensorless Control of Ultrasonic Motors Using Neural Network” (hereinafter referred to as “Non-patent Literature 2”) discusses a technique which controls speeds by estimating the speed of a vibration-type actuator based on the frequency of a driving voltage, a voltage applied to the vibration-type actuator, and the temperature of the vibration-type actuator using a neural network.

Japanese Patent Application Laid-Open No. 2022-71832 discusses a technique which controls a vibration-type actuator using a neural network subjected to machine learning for setting a phase difference between a plurality of driving voltages and frequencies thereof based on a target speed and a position deviation.

In Non-patent Literature 1 and Non-patent Literature 2, a speed estimation technique using a neural network is discussed. The estimation of a speed is performed with use of a drive frequency which is a parameter for controlling the speed of a vibration-type actuator, a current flowing depending on the vibration of the vibration-type actuator, and a driving voltage amplitude of the vibration-type actuator, and, additionally, the detected value of a load torque and the temperature of the vibration-type actuator. In the case of using a load torque to perform estimation, a torque sensor is required in addition to a current detection unit, so that it is difficult to attain a reduction in size of the vibration-type actuator.

Moreover, there is an issue with a decrease in estimated accuracy caused by a difference in frequency characteristics of a current and a detected value obtained by the added torque sensor. In the case of using a temperature to perform estimation, a temperature sensor is required in addition to a current detection unit. Additionally, there is also an issue with a decrease in estimated accuracy caused by a difference in frequency characteristics of a temperature and a detected value of the driving voltage. In either case, thrust (thrust force) is not estimated.

### SUMMARY

Aspects of the present disclosure are generally directed to enabling estimating the thrust or speed of a vibration-type actuator without use of a thrust or speed detection sensor.

According to an aspect of the present disclosure, a device for controlling an actuator is provided, with the actuator including a vibrating body and a contact body, the vibrating body including an elastic body and an electro-mechanical energy converter, the contact body being in contact with the elastic body, the vibrating body and the contact body being configured to move relative to each other in response to vibration of the vibrating body, and the electro-mechanical energy converter includes a first electrode to which a first alternating-current (AC) voltage based on a first AC signal is applied and a second electrode to which a second AC voltage based on a second AC signal is applied, with the device including a neural network that includes a plurality of input layers configured to receive at least a first input value and a second input value, a plurality of intermediate layers connected to the plurality of input layers, and an output layer connected to the plurality of intermediate layers. The output layer outputs an estimated value of at least one of thrust between the vibrating body and the contact body, a speed of the vibrating body relative to the contact body, a resonant frequency of the vibrating body, and a temperature of the vibrating body. The first input value is based on at least one of a phase difference between the first AC signal and the second AC signal, frequencies of the first AC signal and the second AC signal, and an amplitude of the first AC signal or the second AC signal. The second input value is at least one of a measured value of a vibrational state in the vibrating body and a measured value corresponding to an admittance of the vibrating body.

Further features of the present disclosure will become apparent from the following description of exemplary embodiments with reference to the attached drawings.

### BRIEF DESCRIPTION OF THE DRAWINGS

FIGS. 1A, 1B, 1C, 1D, and 1E are diagrams illustrating examples of configurations and vibration shapes of a vibration-type actuator.

FIG. 2 is a diagram illustrating a first configuration of a vibration-type drive device.

FIGS. 3A and 3B are diagrams illustrating a relationship between the speed and the current amplitude difference.

FIGS. 4A and 4B are diagrams illustrating a relationship between the thrust and the current amplitude difference.

FIGS. 5A and 5B are diagrams illustrating an example of a configuration of a vibration-type drive device.

FIGS. 6A and 6B are diagrams illustrating an example of a configuration of a vibration-type drive device.

FIGS. 7A, 7B, 7C, 7D, and 7E are diagrams illustrating examples of a configuration of a neural network.

FIG. 8 is a diagram illustrating a configuration of a device which is used for a neural network to perform learning.

FIG. 9 is a diagram illustrating an example of an operation pattern for a learning operation of a neural network.

FIG. 10 is a diagram illustrating another operation pattern for a learning operation of a neural network.

FIGS. 11A, 11B, and 11C are diagrams illustrating time history data for a learning operation of a neural network.

FIGS. 12A and 12B are diagrams illustrating first and second examples of a configuration of a vibration-type drive device according to a second exemplary embodiment.

FIG. 13 is a diagram illustrating a third example of a configuration of the vibration-type drive device according to the second exemplary embodiment.

FIGS. 14A and 14B are flowcharts illustrating an operation for controlling thrust and the amplitude of a current signal.

FIGS. 15A, 15B, 15C, and 15D are diagrams illustrating examples of configurations of a vibration-type actuator.

FIGS. 16A, 16B, 16C, and 16D are diagrams illustrating examples of configurations of a vibration-type actuator.

FIGS. 17A and 17B are diagrams illustrating an example of a configuration of a vibration-type actuator.

FIG. 18 is a diagram illustrating an example of a configuration of a vibration-type drive device.

FIGS. 19A and 19B are diagrams illustrating examples of alternating-current signal waveforms and a voltage amplitude command waveform.

FIG. 20 is a diagram illustrating an example of a configuration of a vibration-type actuator.

FIG. 21 is a diagram illustrating an example of a configuration of a vibration-type drive device.

FIGS. 22A, 22B, and 22C are diagrams illustrating an example of a configuration of a vibration-type actuator.

FIG. 23 is a diagram illustrating an example of a configuration of a vibration-type drive device.

### DESCRIPTION OF THE EMBODIMENTS

A vibration-type drive device according to each exemplary embodiment of the present disclosure includes a vibration-type actuator, including a vibrating body, which includes an elastic body and an electro-mechanical energy converter, and a contact body, which is in contact with the elastic body, and a control device for the vibration-type actuator.

The vibration-type drive device is a vibration-type drive device in which the vibrating body and the contact body move relative to each other in predetermined movement directions by vibration of the vibrating body.

The above-mentioned vibration is generated in the vibrating body by a voltage applied to the electro-mechanical energy converter.

The vibration-type drive device includes a neural network which is configured to receive, as inputs, a vibrational state of the vibrating body, an applied voltage and an inflowing current to the electro-mechanical energy converter that vary depending on the vibrational state, and states of, for example, frequency, phase, and amplitude indicating a state of the applied voltage. The neural network uses, as an input, at least one of a measured value of the vibrational state in the vibrating body and a measured value corresponding to an admittance characteristic of the vibrating body. Then, the above-mentioned neural network is configured to estimate at least one of thrust occurring between the vibrating body and the contact body, a relative speed between the vibrating body and the contact body, and the temperature and resonant frequency of the vibrating body.

Various exemplary embodiments, features, and aspects of the present disclosure will be described in detail below with reference to the drawings.

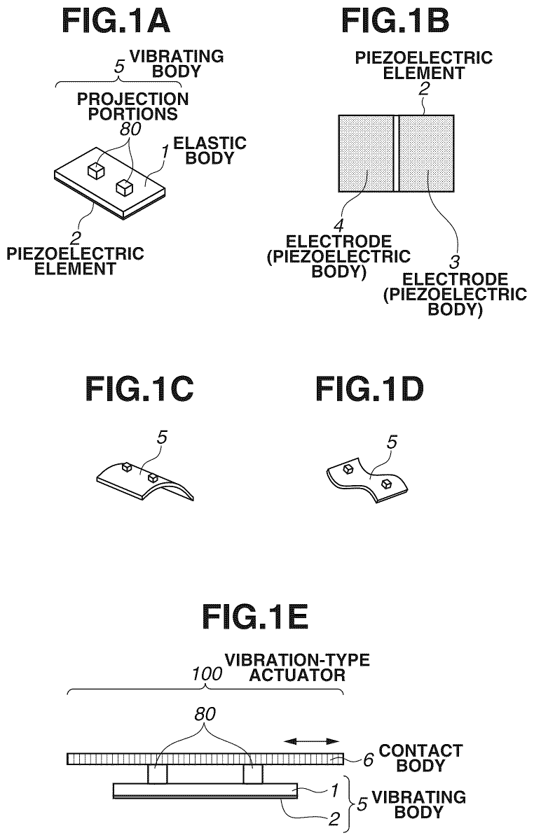

FIGS. 1A, 1B, 1C, 1D, and 1E are diagrams illustrating examples of configurations and vibration shapes of a vibration-type actuator 100 according to a first exemplary embodiment. The configuration and operation principle of the vibration-type actuator 100 according to the first exemplary embodiment are described with reference to FIGS. 1A to 1E.

The vibration-type actuator 100 according to the first exemplary embodiment is configured to include, as illustrated in FIG. 1E, a vibrating body 5 and a contact body 6. The vibrating body 5 is configured with, as illustrated in FIGS. 1A and 1E, a piezoelectric element 2 and an elastic body 1, which includes two projection portions 80, which are in contact with the contact body 6. The piezoelectric element 2 is an example of an electro-mechanical energy converter, constitutes a part of the vibrating body 5, and is a component portion for causing the vibrating body 5 to vibrate.

Moreover, the piezoelectric element 2 is configured with a piezoelectric material and electrodes, with the surface of the piezoelectric material subjected to polarization treatment. As illustrated in FIG. 1B, formed on the piezoelectric element 2 are an electrode 3 and an electrode 4, which are configured to allow respective voltages to be independently applied thereto. Piezoelectric ceramic can be used as the piezoelectric material.

The space between the two electrodes 3 and 4 is electrically insulated, and two alternating-current voltages the phase of each of which is able to independently change are applied to the two electrodes 3 and 4. Moreover, the entire surface of a reverse side of the piezoelectric element 2 is formed as an electrode, and is configured to allow the ground potential to be connected thereto from an opposite side of the piezoelectric element 2 through a via (i.e., a through hole) provided in a part of the piezoelectric element 2. While the piezoelectric material is formed as a single piece of piezoelectric material, the electrode 3, the electrode for the ground potential, and a region of the piezoelectric material sandwiched therebetween them may be collectively referred to as a piezoelectric body 3, for explanation of an electrical circuit. Similar designation also applies to the term piezoelectric body 4.

The contact body 6 illustrated in FIG. 1E is a slider which contacts with the projection portions 80 of the vibrating body 5 at a fixed pressure force applied by a pressure mechanism. The contact body (slider) 6 is configured to move in directions indicated by a double-headed arrow in FIG. 1E by vibrations excited by the vibrating body 5.

FIGS. 1C and 1D are diagrams illustrating examples of vibration modes of the vibrating body 5. FIG. 1C illustrates the vibration shape of a vibration mode which is excited by the vibrating body 5 when alternating-current voltages which are identical in amplitude and phase are applied to the piezoelectric body 3 and the piezoelectric body 4 (an upthrust vibration mode). The upthrust vibration mode is one of the natural vibration modes of the vibrating body 5, and the direction of the natural vibration is a direction approximately perpendicular to a contact surface of the vibrating body 5 with the contact body 6. The degree of identicalness of amplitude and phase can be determined by the user according to the desired quality of vibrational wave.

FIG. 1D illustrates the vibration shape of a vibration mode which is excited by the vibrating body 5 when alternating-current voltages which are identical in amplitude but are opposite in phase are applied to the piezoelectric body 3 and the piezoelectric body 4 (an advancing vibration mode). The advancing vibration mode is one of the natural vibration modes of the vibrating body 5, and the direction of the natural vibration is a direction approximately parallel to a contact surface of the vibrating body 5 with the contact body 6 and approximately coincides with the above-mentioned direction of movement.

As an example, when the phase difference between alternating-current voltages which are applied to the piezoelectric body 3 and the piezoelectric body 4 is set to 0°, a vibration in the vibration mode illustrated in FIG. 1C (upthrust vibration mode) is excited. Moreover, when the phase difference between alternating-current voltages which are applied to the piezoelectric body 3 and the piezoelectric body 4 is set to 180°, a vibration in the vibration mode illustrated in FIG. 1D (advancing vibration mode) is excited.

Additionally, when the phase difference between alternating-current voltages which are applied to the piezoelectric body 3 and the piezoelectric body 4 is set to a phase difference other than 0° and 180° (in actuality, a range of approximately ±1200 from 0° may be used), both of the upthrust vibration mode and the advancing vibration mode, as illustrated in FIGS. 1C and 1D, are simultaneously excited. In this case, the contact body (slider) 6, which is in pressed contact with the projection portions 80 provided in the vibrating body 5, moves in a longitudinal direction of a rectangle of the vibrating body 5. Then, as the phase difference moves away from 0°, the amplitude in the vibration mode illustrated in FIG. 1D (advancing vibration mode) increases, so that the relative speed between the contact body (slider) 6 and the vibrating body 5 increases.

Forces received by the vibrating body 5 include a piezoelectric vibration force which is generated by applying alternating-current voltages to the piezoelectric body 3 and the piezoelectric body 4 and which causes a vibration to be generated in the vibrating body 5, a reaction force which the vibrating body 5 receives from a supporting member, and a reaction force which is received from the contact body (slider) 6. Among these forces, a vibration corresponding to a force (piezoelectric vibration force) which is generated by applying alternating-current voltages to the piezoelectric body 3 and the piezoelectric body 4 constituting the vibrating body 5 is referred to as a first vibrational component, and a vibration occurring in the vibrating body 5 by a reaction force which is received from the contact body (slider) 6 is referred to as a second vibrational component.

The term contact body refers to a member which is in contact with the vibrating body and moves relative to the vibrating body by a vibration generated in the vibrating body. The contact between the contact body and the vibrating body is not limited to direct contact, in which no other member intervenes between the contact body and the vibrating body. As long as the contact body moves relative to the vibrating body by a vibration generated in the vibrating body, the contact between the contact body and the vibrating body can be indirect contact, in which another member intervenes between the contact body and the vibrating body.

The other member, as described herein, is not limited to a member (for example, a high friction material made from a sintered body) independent from the contact body and the vibrating body. The other member can be a surface-treated portion formed by, for example, plating or nitriding treatment.

The term vibrating body refers to a member which includes an elastic body and an electro-mechanical energy converter, i.e. electro-mechanical energy conversion element, and which vibrates with an alternating-current voltage being applied to the electro-mechanical energy converter. The elastic body is made mainly from metal or ceramic, and the electro-mechanical energy converter can also be used as the elastic body.

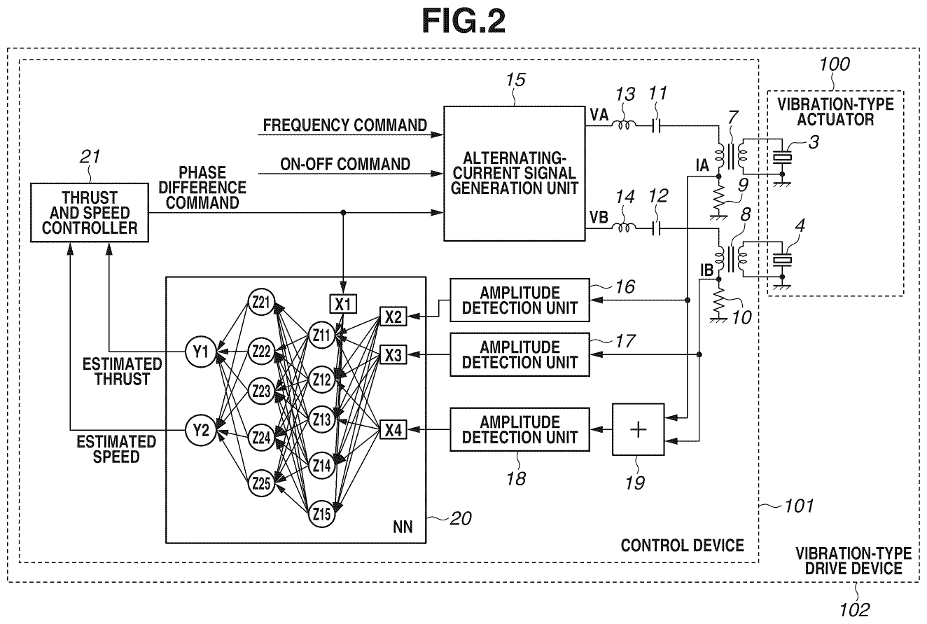

FIG. 2 is a diagram illustrating a first configuration of a vibration-type drive device 102 according to the first exemplary embodiment.

The vibration-type drive device 102 includes a vibration-type actuator 100 and a control device 101 (also referred to as a device) for the vibration-type actuator 100.

The control device 101 includes transformers 7 and 8, resistors 9 and 10, capacitors 11 and 12, inductors 13 and 14, an alternating-current signal generation unit 15, amplitude detection units 16 to 18, an adder 19, a neural network 20, and a thrust and speed controller 21.

The configuration illustrated in FIG. 2 includes the vibration-type actuator 100, a generation unit 15 for alternating-current voltages to be applied to the vibration-type actuator 100, an estimation unit for the thrust and speed of the vibration-type actuator 100, and a portion concerning speed and thrust control.

The generation unit for alternating-current voltages is described herein. The alternating-current signal generation unit 15 generates two-phase alternating-current signal (first signal) VA and alternating-current signal (second signal) VB based on a frequency command and an ON-Off command which are output from a command unit and a phase difference command which is output from the thrust and speed controller 21 described below.

The alternating-current signal VA and the alternating-current signal VB are connected to the primary side winding wires of the transformer 7 and the transformer 8 via series resonance circuits composed of the inductors 13 and 14 and the capacitors 11 and 12, respectively.

In the present example, to perform waveform shaping or suppress a change of amplitudes of voltages applied to the piezoelectric body 3 and the piezoelectric body 4, the transformer 7 and the transformer 8 are described as being connected via the series resonance circuits, only one of the inductor and the capacitor need be connected.

The voltages input to the primary side winding wires of the transformer 7 and the transformer 8 are boosted. The boosted voltages are then applied as a first drive voltage and a second drive voltage to the piezoelectric body 3 and the piezoelectric body 4, respectively, constituting the vibrating body 5 of the vibration-type actuator 100 connected to the secondary side winding wires of the transformer 7 and the transformer 8. As mentioned above, for explanation of an electrical circuit, the piezoelectric body 3 and the piezoelectric body 4 are a part of the integral piezoelectric element 2.

The inductor values of the secondary side winding wires of the transformer 7 and the transformer 8 are frequency-matched with braking capacities of the piezoelectric body 3 and the piezoelectric body 4. This causes currents approximately proportional to the vibration speeds of distortions occurring in the piezoelectric body 3 and the piezoelectric body 4 to flow through the primary side winding wires of the transformer 7 and the transformer 8.

Resistors 9 and 10 used for current detection are connected in series to respective primary side winding wires of transformers 7 and 8, and are used to detect currents flowing through the primary side winding wires of the transformer 7 and the transformer 8, thus generating a current signal IA and a current signal IB. A relationship between the current signal IA and the current signal IB and the vibration of the vibrating body 5 is separately described below.

Estimation of thrust and speed is performed by the trained neural network (NN) 20. The NN 20 is configured with four input layers X1 to X4, intermediate layers Z11 to Z25 as two layers×5, and two output layers Y1 and Y2, and is configured such that the output layer Y1 outputs an estimated thrust and the output layer Y2 outputs an estimated speed.

Four signals are input to the input layers X1 to X4 of the NN 20. To the input layer X1, a phase difference command which the thrust and speed controller 21 outputs is input. To the input layers X2 to X4, output signals from the amplitude detection units 16 to 18 are input.

The amplitude detection unit 16 detects the amplitude of the current signal IA. The amplitude detection unit 17 detects the amplitude of the current signal IB. The adder 19 outputs a signal obtained by adding the current signal IA and the current signal IB. The amplitude detection unit 18 detects the amplitude of the signal obtained by adding the current signal IA and the current signal IB, which the adder 19 outputs. The signal which the adder 19 outputs is a signal corresponding to the vibrational state illustrated in FIG. 1C, and the amplitude thereof is equivalent to an amplitude in the upthrust vibration mode of the vibrating body 5.

Each of the amplitude detection units 16 to 18 extracts, from the input signal, a basic wave component of the input signal by a band-pass filter or low-pass filter and thus detects the amplitude thereof. Moreover, each of the amplitude detection units 16 to 18 can convert the value of the detected amplitude with use of predetermined functional operations or a look-up table and then input the converted amplitude to the NN 20.

The vibrating body 5 receives a reaction force which is generated according to a relative speed relative to the contact body (slider) 6 and a generated relative force, and a second vibrational component caused by the received reaction force is superposed on the vibrating body 5, so that the amplitudes of the current signal IA and the current signal IB change. The NN 20 performs the estimation of speed and thrust based on such changes of the amplitudes of current signals.

As described above, the vibration-type actuator 100 includes the vibrating body 5, which includes the elastic body 1 and the piezoelectric element 2, and the contact body 6, which is in contact with the elastic body 1, and, by the vibration of the vibrating body 5, the vibrating body 5 moved relative to the contact body 6 in predetermined movement directions.

The piezoelectric element 2, which is an example of an electro-mechanical energy converter, includes the first electrode 3, to which the first alternating-current voltage that is based on the first alternating-current signal VA is applied, and the second electrode 4, to which the second alternating-current voltage that is based on the second alternating-current signal VB is applied.

The first input layer X1 receives, as an input, a value that is based on a phase difference between the first alternating-current signal VA and the second alternating-current signal VB. The second input layer X2 receives, as an input, a value that is based on the amplitude of the first current signal IA that is based on the first alternating-current signal VA. The third input layer X3 receives, as an input, a value that is based on the amplitude of the second current signal IB that is based on the second alternating-current signal VB. The fourth input layer X4 receives, as an input, a value that is based on the amplitude of a signal obtained by adding the first current signal IA and the second current signal IB.

The first output layer Y1 outputs an estimated value of thrust occurring between the vibrating body 5 and the contact body 6.

The second output layer Y2 outputs an estimated value of a relative speed between the vibrating body 5 and the contact body 6.

The thrust and speed controller 21 controls a phase difference between the first alternating-current signal VA and the second alternating-current signal VB based on an estimated value of the thrust output from the first output layer Y1 and an estimated value of the relative speed output from the second output layer Y2.

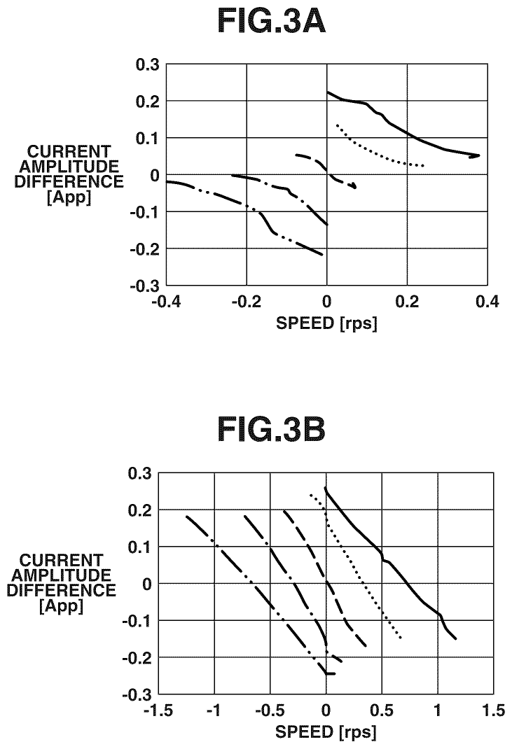

FIGS. 3A and 3B are diagrams illustrating a relationship between differences in current amplitude and speed, with the difference in current amplitude being a difference in amplitude of the current signal IA and an amplitude of the current signal IB. FIG. 3A illustrates an example in a case where the amplitude of the current signal IA added to the current signal IB is relatively small. FIG. 3B illustrates an example in a case where the amplitude of the current signal IA added to the current signal IB is relatively large.

The line types in each of FIGS. 3A and 3B indicate differences of the phase difference between the alternating-current signal VA and the alternating-current signal VB, with a solid line representing 90°, a dotted line representing 45°, a dashed line representing 0°, a dashed-dotted line representing −45°, and a dashed-two dotted line representing −90°.

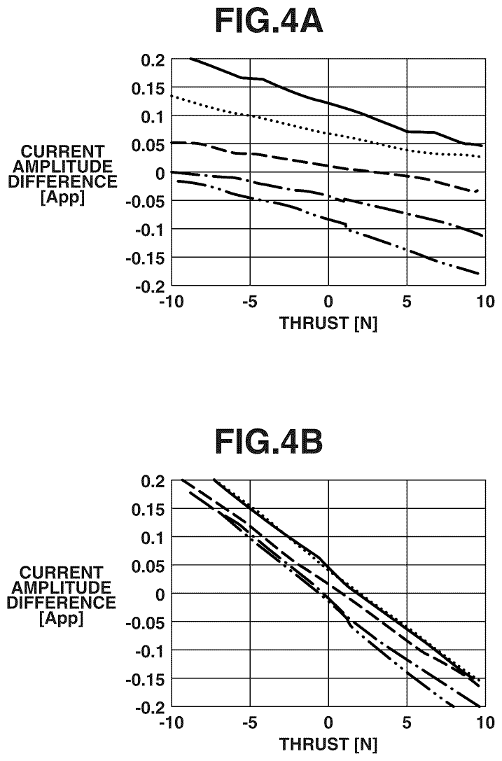

FIGS. 4A and 4B are diagrams illustrating a relationship between differences of current amplitude and the thrust, with the difference being the current signal IA subtracted from the amplitude of the current signal IB. FIG. 4A illustrates an example in a case where the amplitude of the current signal IA added to the current signal IB is relatively small. FIG. 4B illustrates an example in a case where the amplitude of the current signal IA added to the current signal IB is relatively large.

The line types in each of FIGS. 4A and 4B indicate differences of the phase difference between the alternating-current signal VA and the alternating-current signal VB, with a solid line representing 90°, a dotted line representing 45°, a dashed line representing 0°, a dashed-dotted line representing −45°, and a dashed-two dotted line representing −90°.

Thus, it is understood that the respective amplitudes of the current signal IA, the current signal IB, the current signal IA added to the current signal IB, a phase difference between the alternating-current signal VA and the alternating-current signal VB, the speed, and the thrust have a strong correlation with each other.

Therefore, the NN 20 performs learning in such a way as to receive, as inputs, the respective amplitudes of the current signal IA, the current signal IB, the current signal IA added to the current signal IB, a phase difference between the alternating-current signal VA, and the alternating-current signal VB, to then output the speed and the thrust. Thus, the NN 20 outputs estimated values of speed and thrust.

The estimated thrust and the estimated speed, which are results of calculation performed by the NN 20, are input to the thrust and speed controller 21. Then, the thrust and speed controller 21 outputs a phase difference command for setting a phase difference between the alternating-current signal VA and the alternating-current signal VB according to a difference between a speed command output from a command unit and the estimated speed and the estimated thrust, so that the speed is controlled in such a way as to follow the speed command.

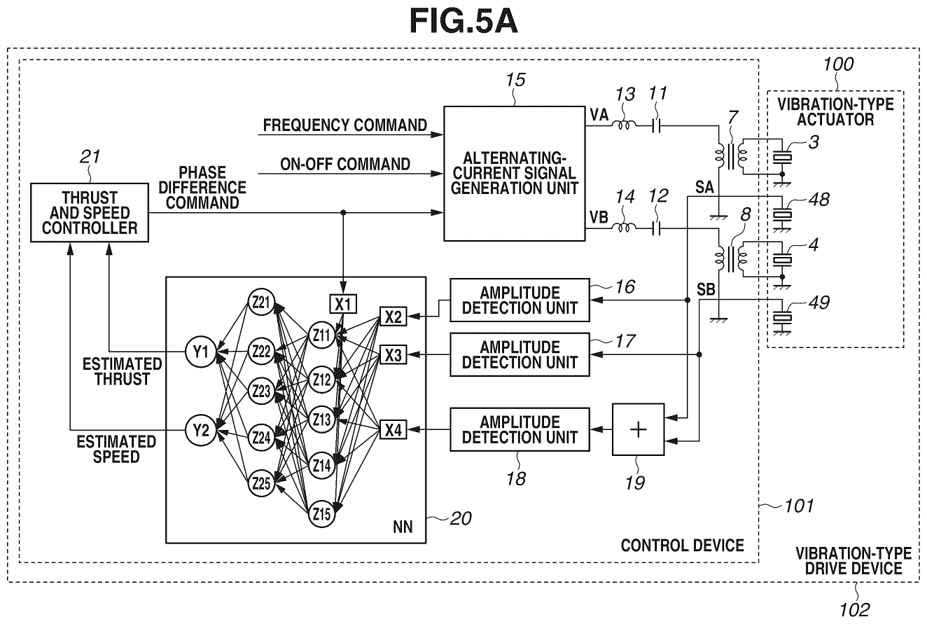

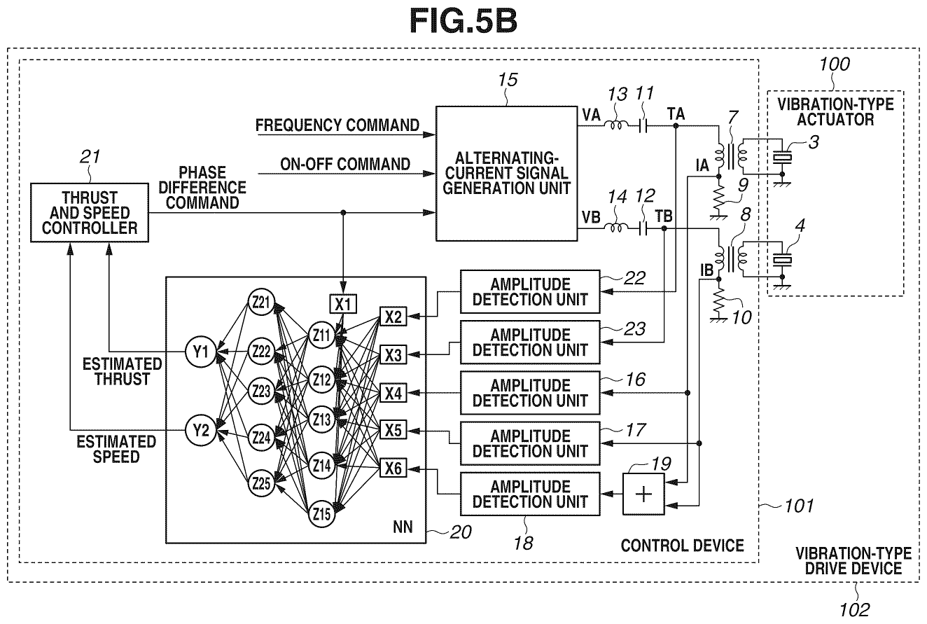

FIG. 5A is a diagram illustrating a second configuration of the vibration-type drive device 102 according to the first exemplary embodiment. FIG. 5A illustrates a case where the vibrating body 5 is provided with piezoelectric elements for detecting vibrations separately from the piezoelectric elements for driving. Elements similar to the elements illustrated in FIG. 2 are assigned the same reference numbers. For conciseness, the detailed description thereof is incorporated here by reference.

As illustrated in FIG. 5A, piezoelectric body 48 and a piezoelectric body 49 are provided as piezoelectric elements for vibration detection. The piezoelectric body 48 outputs a vibration detection signal SA. The piezoelectric body 49 outputs a vibration detection signal SB. Moreover, the piezoelectric body 48 is provided in superposition on the piezoelectric body 3 and the piezoelectric body 49 is provided in superposition on the piezoelectric body 4.

The piezoelectric bodies 48 and 49, being provided in superposition, receive almost the same distortion as the piezoelectric bodies subjected to superposition and, thus, are able to accurately detect the vibrations of the piezoelectric body 3 and the piezoelectric body 4 for driving. The piezoelectric bodies 48 and 49 for vibration detection are not limited to those provided separately from the piezoelectric bodies 3 and 4 for driving. With regard to the piezoelectric bodies 48 and 49 for vibration detection, a configuration in which electrode regions for detection independent from the driving electrodes are provided on the piezoelectric bodies 3 and 4 for driving and are then used as piezoelectric bodies 48 and 49 for vibration detection can be employed.

The amplitude detection unit 16 detects the amplitude of the vibration detection signal SA. The amplitude detection unit 17 detects the amplitude of the vibration detection signal SB. The adder 19 outputs a signal obtained by adding the vibration detection signals SA and SB. The amplitude detection unit 18 receives, as an input, an output signal from the adder 19 and then detects the amplitude of the signal obtained by adding the vibration detection signals SA and SB. The input layer X2 receives, as an input, a signal detected by the amplitude detection unit 16. The input layer X3 receives, as an input, an amplitude detected by the amplitude detection unit 17. The input layer X4 receives, as an input, an amplitude detected by the amplitude detection unit 18.

While FIGS. 3A and 3B and FIGS. 4A and 4B illustrate relationships between a difference between the amplitudes of the first current signal IA and the second current signal IB and the speed and the thrust, a difference between the amplitudes of the vibration detection signal SA and the vibration detection signal SB shows a similar tendency. Therefore, even in the configuration illustrated in FIG. 5A, the NN 20 is able to, by preliminarily performing learning, estimate the thrust and the speed.

As described above, the first input layer X1 receives, as an input, a value that is based on a phase difference between the first alternating-current signal VA and the second alternating-current signal VB. The second input layer X2 receives, as an input, a value that is based on the amplitude of the first vibration detection signal SA that is based on the first electrode 3 of the piezoelectric element 2. The third input layer X3 receives, as an input, a value that is based on the amplitude of the second vibration detection signal SB that is based on the second electrode 4 of the piezoelectric element 2. The fourth input layer X4 receives, as an input, a value that is based on the amplitude of a signal obtained by adding the first vibration detection signal SA and the second vibration detection signal SB.

The first output layer Y1 outputs an estimated value of thrust occurring between the vibrating body 5 and the contact body 6.

The second output layer Y2 outputs an estimated value of a relative speed between the vibrating body 5 and the contact body 6.

FIG. 5B is a diagram illustrating a third configuration of the vibration-type drive device 102 according to the first exemplary embodiment. The configuration illustrated in FIG. 5B differs from the configuration illustrated in FIG. 2 in that the number of input layers of the NN 20 increases from 4 to 6.

The added layers X2 and X3 receive, as inputs, the respective amplitudes of the primary side input voltages TA and TB of the transformers 7 and 8, respectively. An amplitude detection unit 22 detects the amplitude of the primary side input voltage TA of the transformer 7, and an amplitude detection unit 23 detects the amplitude of the primary side input voltage TB of the transformer 8. The input layer X2 receives, as an input, the amplitude of the primary side input voltage TA of the transformer 7 detected by the amplitude detection unit 22. The input layer X3 receives, as an input, the amplitude of the primary side input voltage TB of the transformer 8 detected by the amplitude detection unit 23.

An input layer X4 illustrated in FIG. 5B corresponds to the input layer X2 illustrated in FIG. 2. An input layer X5 illustrated in FIG. 5B corresponds to the input layer X3 illustrated in FIG. 2. An input layer X6 illustrated in FIG. 5B corresponds to the input layer X4 illustrated in FIG. 2.

Since the respective amplitudes of the primary side input voltages TA and TB of the transformers 7 and 8 change together with the state of being input to other input layers according to the admittance characteristic which changes depending on the vibrational state and temperature of the vibrating body 5, the estimated accuracy for thrust and speed may be improved.

As described above, the first input layer X1 receives, as an input, a value that is based on a phase difference between the first alternating-current signal VA and the second alternating-current signal VB. The second input layer X2 receives, as an input, a value that is based on the amplitude of the first voltage signal TA that is based on the first alternating-current signal VA. The third input layer X3 receives, as an input, a value that is based on the amplitude of the second voltage signal TB that is based on the second alternating-current signal VB.

The fourth input layer X4 receives, as an input, a value that is based on the amplitude of the first current signal IA. The fifth input layer X5 receives, as an input, a value that is based on the amplitude of the second current signal IB. The sixth input layer X6 receives, as an input, a value that is based on the amplitude of a signal obtained by adding the first current signal IA and the second current signal IB.

The first output layer Y1 outputs an estimated value of thrust occurring between the vibrating body 5 and the contact body 6.

The second output layer Y2 outputs an estimated value of a relative speed between the vibrating body 5 and the contact body 6.

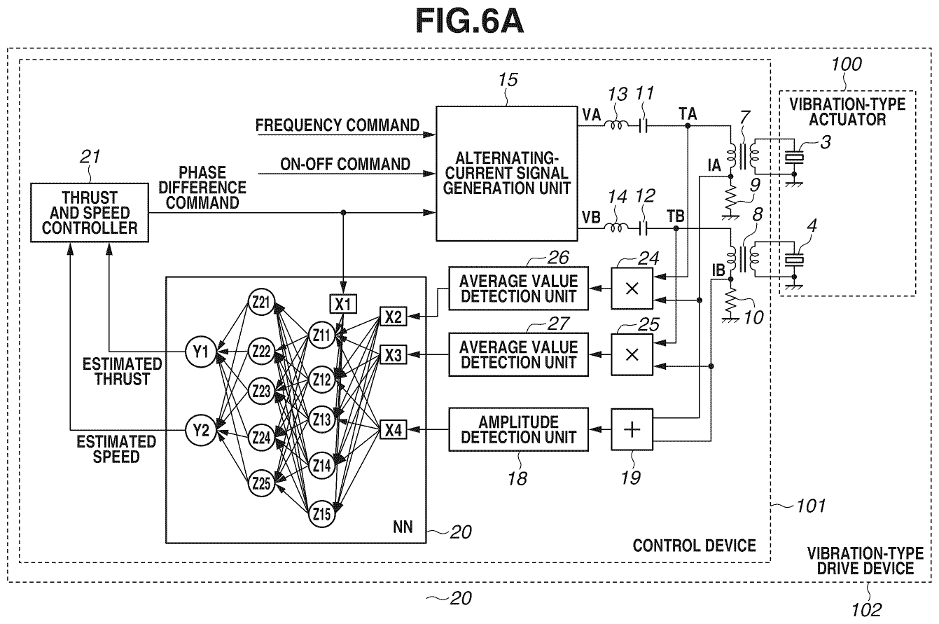

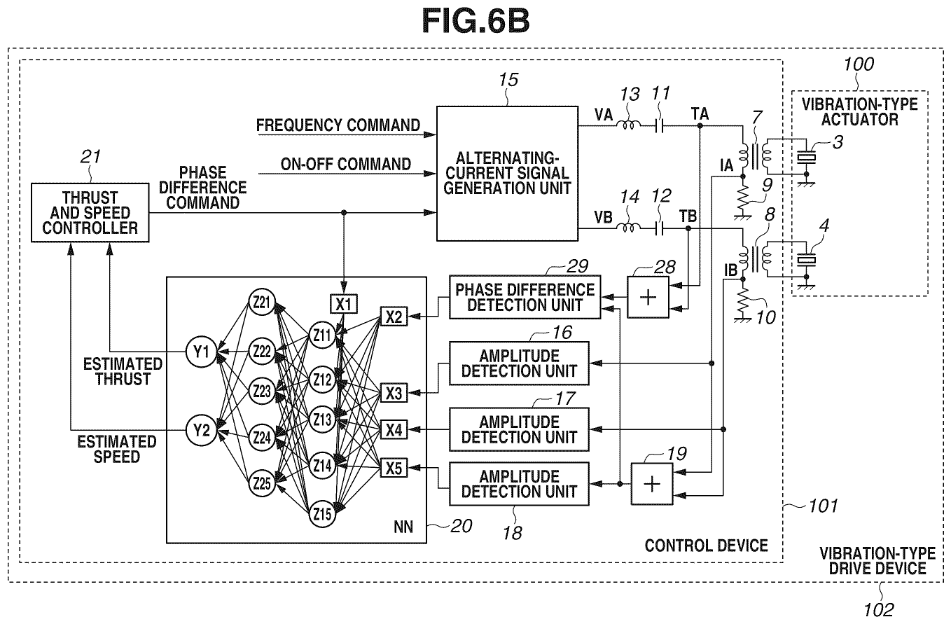

FIG. 6A is a diagram illustrating a fourth configuration of the vibration-type drive device 102 according to the first exemplary embodiment. In the above-described configuration illustrated in FIG. 2, the respective amplitudes of the current signal IA and the current signal IB are detected by the amplitude detection units 16 and 17 and are then input to the input layers X2 and X3 of the NN 20.

In the configuration illustrated in FIG. 6A, electric powers are obtained and input by multiplying the primary side input voltages TA and TB of the transformers 7 and 8 by the current signals IA and IB, respectively. A multiplier 24 multiplies the primary side input voltage TA of the transformer 7 by the current signal IA and outputs the product of the primary side input voltage TA and the current signal IA to an average value detection unit 26. A multiplier 25 multiplies the primary side input voltage TB of the transformer 8 by the current signal IB and outputs the product of the primary side input voltage TB and the current signal IB to an average value detection unit 27.

The average value detection unit 26 detects an average value of the product of the primary side input voltage TA and the current signal IA, and outputs the average value of the product of the primary side input voltage TA and the current signal IA to the input layer X2. The average value detection unit 27 detects an average value of the product of the primary side input voltage TB and the current signal IB, and outputs the average value of the product of the primary side input voltage TB and the current signal IB to the input layer X3.

The input layer X2 receives, as an input, the average value of the product of the primary side input voltage TA and the current signal IA as an average value of the primary side electric power of the transformer 7. The input layer X3 receives, as an input, the average value of the product of the primary side input voltage TB and the current signal IB as an average value of the primary side electric power of the transformer 8.

The difference between electric power generated on the alternating-current signal VA side and electric power generated on the alternating-current signal VB side has a correlation with a difference between the respective amplitudes of the current signal IA and the current signal IB, changes depending on the vibrational state, and has a similar correlation with thrust and speed. Accordingly, the NN 20 preliminarily learns a relationship with differences in electric power, thus becoming able to estimate thrust and speed.

As described above, the first input layer X1 receives, as an input, a value that is based on a phase difference between the first alternating-current signal VA and the second alternating-current signal VB. The second input layer X2 receives, as an input, a value that is based on an average value of the first electric power signal that is based on the first alternating-current signal VA. The third input layer X3 receives, as an input, a value that is based on an average value of the second electric power signal that is based on the second alternating-current signal VB. The fourth input layer X4 receives, as an input, a value that is based on the amplitude of a signal obtained by adding the first current signal IA and the second current signal IB.

The first output layer Y1 outputs an estimated value of thrust occurring between the vibrating body 5 and the contact body 6.

The second output layer Y2 outputs an estimated value of a relative speed between the vibrating body 5 and the contact body 6.

FIG. 6B is a diagram illustrating a fifth configuration of the vibration-type drive device 102 according to the first exemplary embodiment. The configuration illustrated in FIG. 6B differs from that illustrated in FIG. 2 in that the number of input layers of the NN 20 increases from 4 to 5.

An adder 28 outputs, to a phase difference detection unit 29, a signal obtained by adding the respective primary side input voltages TA and TB of the transformers 7 and 8. The phase difference detection unit 29 detects a phase difference between a signal which the adder 19 outputs and a signal which the adder 28 outputs, and outputs the detected phase difference to the input layer X2. The detected phase difference represents a state corresponding to a difference between a resonant frequency and a vibrational frequency in the upthrust vibration mode illustrated in FIG. 1C, and changes according to the vibrational state of the vibrating body 5. The input layer X2 receives, as an input, a phase difference between a signal which the adder 19 outputs and a signal which the adder 28 outputs. The input layers X3 to X5 illustrated in FIG. 6B correspond to the input layers X2 to X4 illustrated in FIG. 2, respectively. Thus, the NN 20 provided improved estimation accuracy of thrust and speed.

As described above, the first input layer X1 receives, as an input, a value that is based on a phase difference between the first alternating-current signal VA and the second alternating-current signal VB. The second input layer X2 receives, as an input, a value that is based on a phase difference between a sum signal of the first voltage signal TA and the second voltage signal TB and a sum signal of the first current signal IA and the second current signal IB.

The third input layer X3 receives, as an input, a value that is based on the amplitude of the first current signal IA. The fourth input layer X4 receives, as an input, a value that is based on the amplitude of the second current signal IB. The fifth input layer X5 receives, as an input, a value that is based on the amplitude of a signal obtained by adding the first current signal IA and the second current signal IB.

The first output layer Y1 outputs an estimated value of thrust occurring between the vibrating body 5 and the contact body 6.

The second output layer Y2 outputs an estimated value of a relative speed between the vibrating body 5 and the contact body 6.

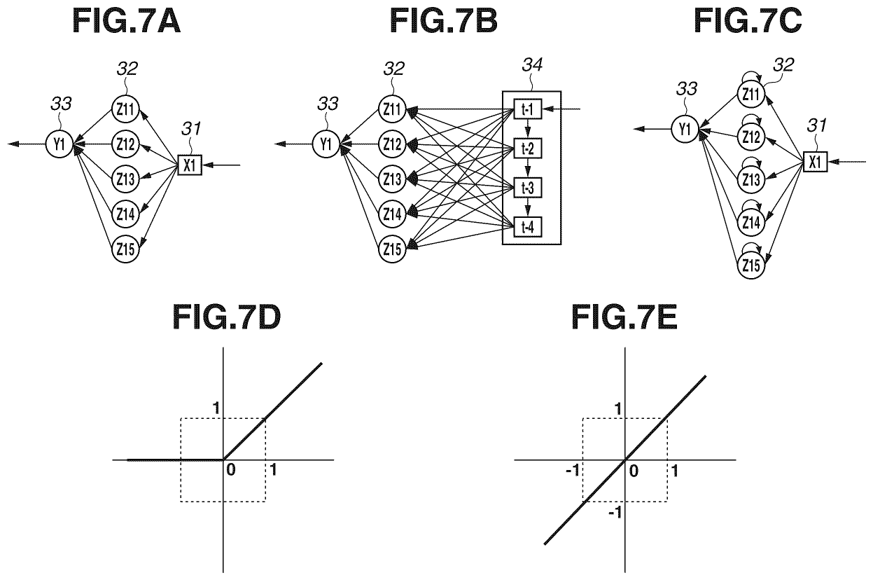

FIGS. 7A, 7B, 7C, 7D, and 7E are diagrams illustrating examples of a configuration of a neural network. FIG. 7A is a diagram illustrating a basic configuration of the neural network, which includes an input layer 31, intermediate layers 32, and an output layer 33. While FIG. 7A illustrates one input layer 31, five intermediate layers 32, and one output layer 33, the input layer can include a plurality of input layers.

FIG. 7D illustrates an example of an activation function which is used in the intermediate layers 32. The activation function is usually a function performed by a rectified linear unit (ReLU).

FIG. 7E illustrates an example of an activation function which is used in the output layer 33, which is may be referred to as an identity function and directly outputs an input.

FIG. 7B illustrates a neural network configured such that time-series signals are connected to an input layer 34. The input layer 34 receives, as an input, an input signal for each isochronal sample. At time step t-1, an input signal 1 sample time ago is retained, at time step t-2, an input signal 2 sample times ago is retained, at time step t-3, an input signal 3 sample times ago is retained, and, at time step t-4, an input signal 4 sample times ago is retained. The time steps t-1 to t-4 of the input layer 34 are sequentially outputting time-series signals to the intermediate layers 32. The input layer 34 outputs a time-series plurality of input values to a plurality of intermediate layers 32. In this way, inputting time-series signals to the neural network enables performing high-accuracy estimation of speed and thrust with respect to a fluctuating input signal.

FIG. 7C illustrates a neural network in which a route for returning the state of an intermediate layer 32 to the same intermediate layer 32 is provided. The intermediate layer 32 is a recursive connection for returning an output to an input. The configuration illustrated in FIG. 7C is a configuration having an advantageous effect of increasing the estimated accuracy as with the configuration illustrated in FIG. 7B, and may be referred to as a recurrent neural network.

Since the vibration-type actuator 100 quickly responds to vibration, to estimate speed and thrust, an estimation compatible with a fluctuating speed of vibration is important. The configurations illustrated in FIG. 7B and FIG. 7C are effective for improving the estimate accuracy compatible with a fluctuating speed of vibration.

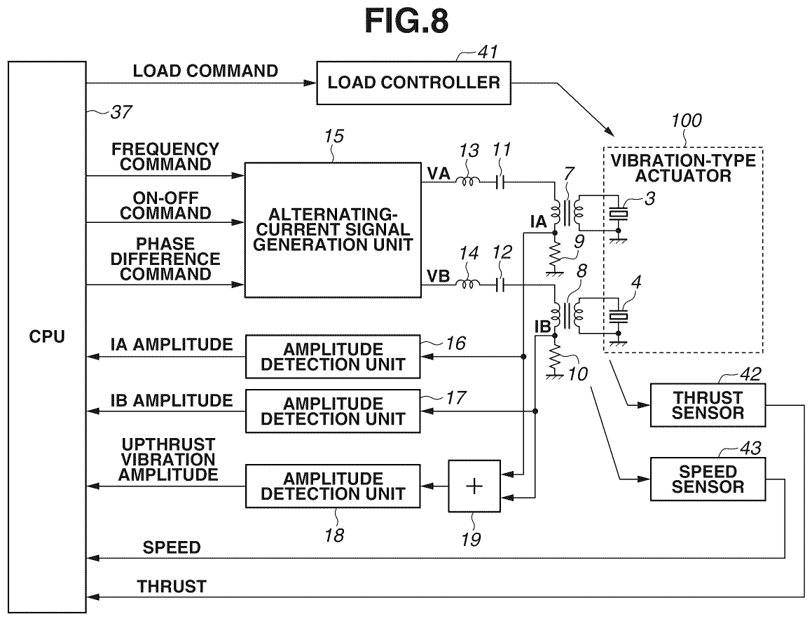

FIG. 8 illustrates a configuration of a device which is used for the NN 20 to perform learning. A central processing unit (CPU) 37 outputs a load command to a load controller 41. The CPU 37 also outputs a frequency command, an ON-OFF command, and a phase difference command to the alternating-current signal generation unit 15.

The amplitude detection unit 16 outputs an IA amplitude (the amplitude of the first current signal IA) to the CPU 37. The amplitude detection unit 17 outputs an IB amplitude (the amplitude of the second current signal IB) to the CPU 37. The amplitude detection unit 18 outputs an upthrust vibration amplitude (the amplitude of upthrust vibration) to the CPU 37.

The CPU 37 measures and collects the IA amplitude, the IB amplitude, and the upthrust vibration amplitude, which are vibrational states of the vibrating body 5. The CPU 37 also measures and collects the speed and thrust of the vibration-type actuator 100 obtained when the vibration-type actuator 100 has been driven on various drive conditions. Thus, the CPU 37 generates a learned model (trained model) of the NN 20.

A thrust sensor 42, which measures the thrust of the vibration-type actuator 100, outputs the measured thrust to the CPU 37. A speed sensor 43, which measures the speed of the vibration-type actuator 100, outputs the measured speed to the CPU 37.

In addition to performing data collection for a learning operation of the NN 20 and causing the NN 20 to perform learning, the CPU 37 controls the thrust and the upthrust vibration amplitude. Regarding the control of the thrust, the load controller 41 controls loads, such as brakes and motors, connected to the vibration-type actuator 100 according to the load command received from the CPU 37. The CPU 37 outputs the load command according to a predetermined thrust command sequence in such a manner that the thrust output from the thrust sensor 42 follows up the thrust command sequence, thus putting a predetermined load on the vibration-type actuator 100.

Regarding the CPU 37 controlling the upthrust vibration amplitude, the CPU 37 controls the frequency command based on a predetermined upthrust vibration amplitude command sequence in such a manner that the upthrust vibration amplitude output from the amplitude detection unit 18 follows up the upthrust vibration amplitude command sequence.

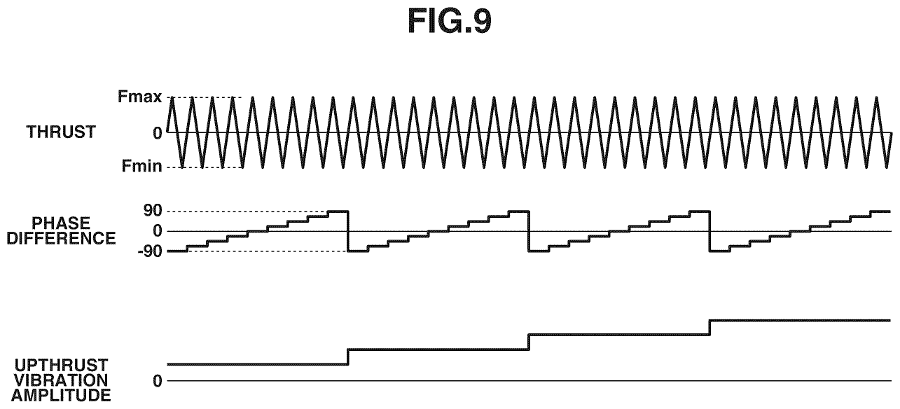

FIG. 9 illustrates a first example of a sequence for a thrust command, an upthrust vibration amplitude command, and a phase difference command, which are used for learning. The CPU 37 operates the thrust command in a triangular wave pattern, and operates the load command in such a manner that the thrust reciprocates between a minimum value Fmin and a maximum value Fmax, switching the phase difference in a stepwise manner from −90° to 90°, and switching the upthrust vibration amplitude in a stepwise manner each time repeating setting of the phase difference.

The CPU 37 collects values of the IA amplitude, the IB amplitude, and the upthrust vibration amplitude, which are vibrational states during an operation of such a sequence being performed, and values of the speed and thrust of the vibration-type actuator 100, thus performing accumulation of learning data for the NN 20.

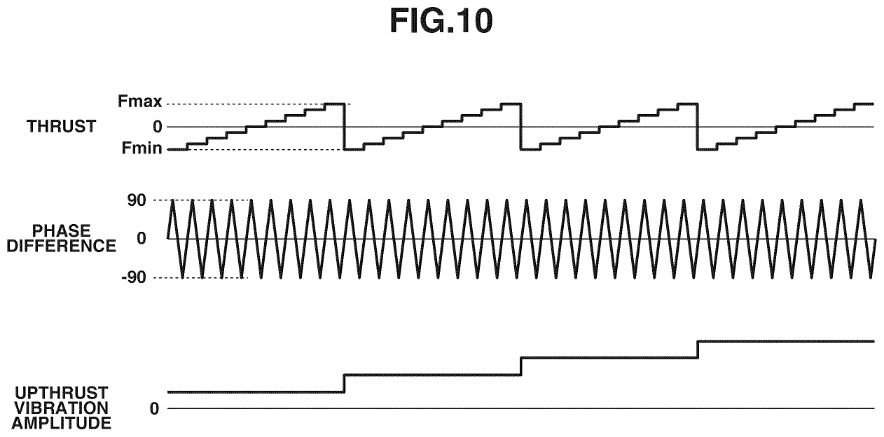

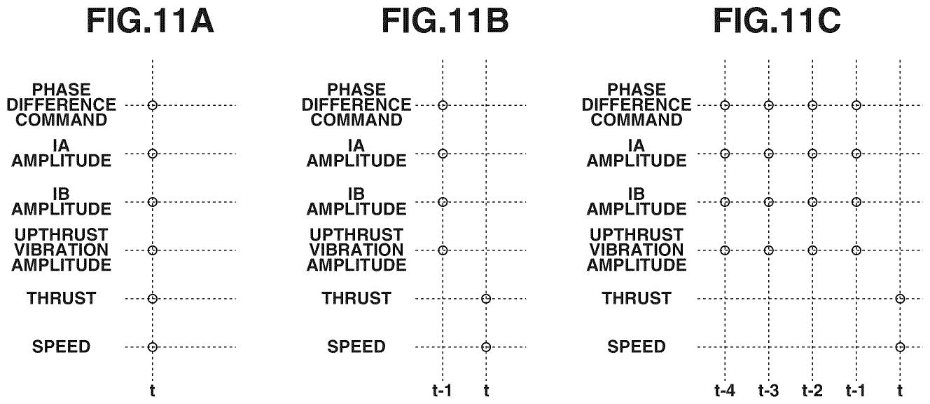

FIG. 10 is a diagram illustrating another example of an operation pattern of a neural network. In FIG. 10, a sequence for a thrust command, an upthrust vibration amplitude command, and a phase difference command are used for learning. In the example illustrated in FIG. 9, the CPU 37 sweeps the thrust in a triangular wave pattern. In the example illustrated in FIG. 10, the CPU 37 sweeps the phase difference command in a triangular wave pattern. Since, even when momentarily exhibiting the same state according to the fluctuating speed of a phase difference or thrust, the vibrational state of the vibration-type actuator 100 has different responses, performing accumulation of learning data on various conditions in addition to the examples illustrated in FIG. 9 and FIG. 10 is important in building a good learning model.

FIGS. 11A, 11B, and 11C are diagrams illustrating time history data used for a learning operation of the NN 20. The NN 20 is a model which estimates thrust and speed from states of the phase difference command, the IA amplitude, the IB amplitude, and the upthrust vibration amplitude. FIGS. 11A to 11C illustrate, at the time of estimating thrust and speed obtained at time t, data obtained at a time for use as data to be input to the input layer.

FIG. 11A illustrates, with states obtained at time t being input to the input layer, learning a model which estimates thrust and speed to be obtained at time t.

FIG. 11B illustrates, with states obtained at time t-1 being input to the input layer, learning a model which estimates thrust and speed to be obtained at time t.

FIG. 11C illustrates, based on states obtained at time t-4 to time t-1, a learning model which estimates thrust and speed to be obtained at time t. This is equivalent to the case of using a neural network in which time-series data such as that illustrated in FIG. 7B is input to the input layer 34. The configuration using such time-series data enables configuring a neural network capable of estimating thrust and speed with a broad frequency band.

Even when the method of learning illustrated in FIGS. 11A and 11B is used, using a recurrent neural network, such as that illustrated in FIG. 7C, may result in a frequency band broadening.

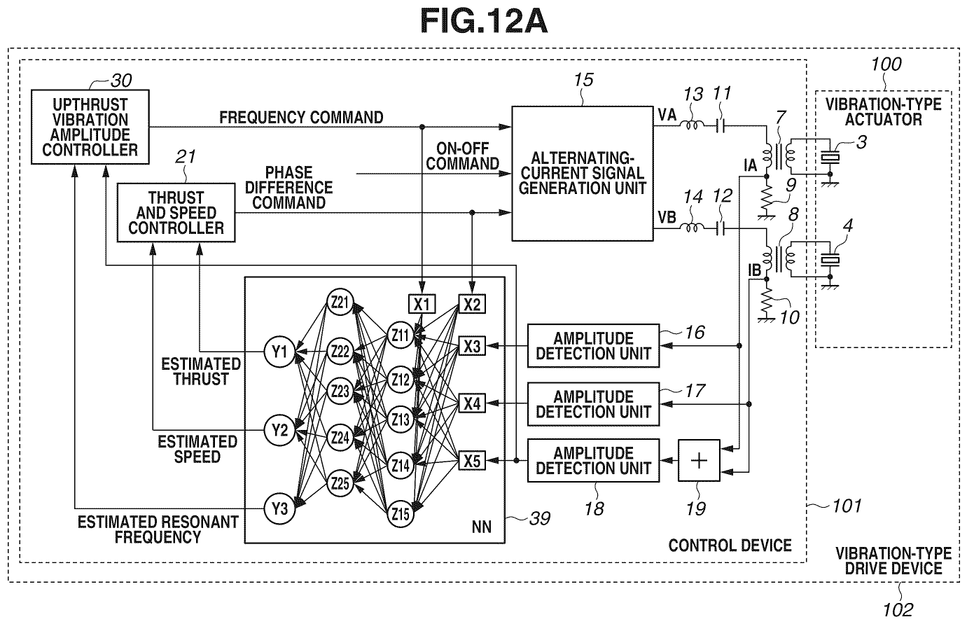

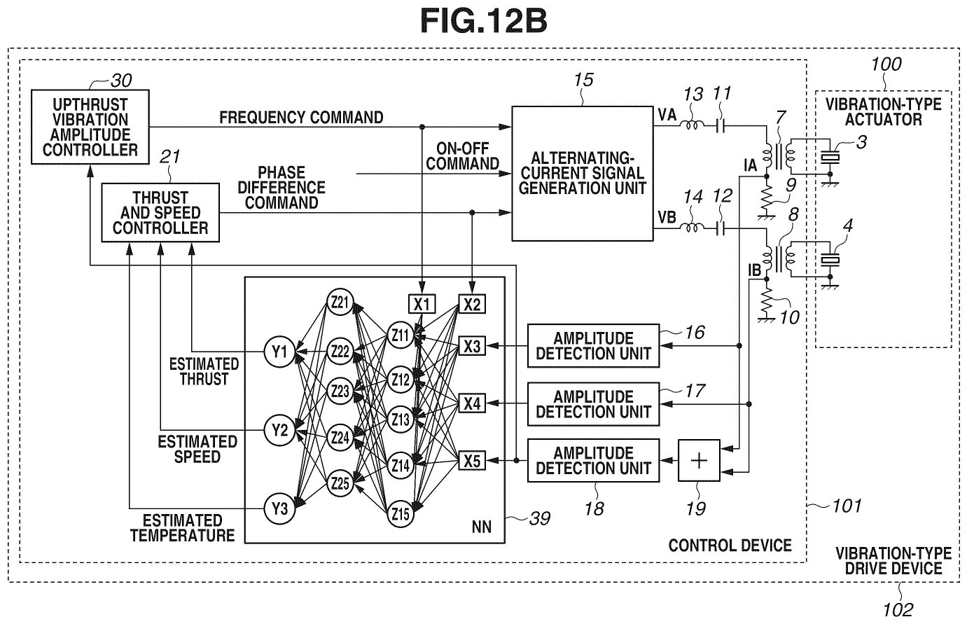

FIGS. 12A and 12B are diagrams illustrating first and second examples of a configuration of a vibration-type drive device 102 according to a second exemplary embodiment. In the first example, performing estimation of thrust and speed using a neural network is described. In the second exemplary example, performing estimation of the resonant frequency and temperature of the vibration-type actuator 100 is described.

FIG. 12A is a diagram illustrating a first example of the configuration of the vibration-type drive device 102 according to the second exemplary embodiment. Elements similar to the elements illustrated in FIG. 2 are assigned the same reference numbers. For conciseness, the detailed description thereof is incorporated here by reference.

The vibration-type drive device 102 includes a learned (NN 39. The NN 39 differs from the NN 20 in that a frequency command signal for designating the frequency pf the alternating-current signal VA is input to the input layer X1 and in that an estimated value of the resonant frequency of the vibrating body 5 of the vibration-type actuator 100 is output from an output layer Y3.

The NN 39 includes input layers X1 to X5 and output layers Y1 to Y3. The input layers X2 to X5 illustrated in FIG. 12A correspond to the input layers X1 to X4 illustrated in FIG. 2, respectively. The input layer X1 receives, as an input, the frequency command signal for designating the frequency of the alternating-current signal VA from an upthrust vibration amplitude controller 30. The output layer Y3 outputs an estimated value of the resonance frequency (estimated resonance frequency) to the upthrust vibration amplitude controller 30.

The NN 39, which has preliminarily performed learning, is configured to output estimated values of thrust, speed, and resonant frequency from the output layers Y1 to Y3, respectively.

The upthrust vibration amplitude controller 30 controls a frequency command for the alternating-current signal VA according to an output signal of the amplitude detection unit 18 in such a manner that an output signal of the amplitude detection unit 18 equivalent to the amplitude in the upthrust vibration mode of the vibrating body 5 becomes a predetermined value. The upthrust vibration amplitude controller 30 is configured to adjust a control amount for the frequency command according to the estimated resonant frequency which the NN 39 outputs, thus adjusting an operation amount for frequency in such a way as to prevent the frequency command from exceeding the estimated resonant frequency.

As described above, the first input layer X1 receives, as an input, a value that is based on the frequencies of the first alternating-current signal VA and the second alternating-current signal VB. The frequencies of the first alternating-current signal VA and the second alternating-current signal VB are identical to each other. The second input layer X2 receives, as an input, a value that is based on a phase difference between the first alternating-current signal VA and the second alternating-current signal VB.

The third input layer X3 receives, as an input, a value that is based on the amplitude of the first current signal IA. The fourth input layer X4 receives, as an input, a value that is based on the amplitude of the second current signal IB. The fifth input layer X5 receives, as an input, a value that is based on the amplitude of a signal obtained by adding the first current signal IA and the second current signal IB.

The first output layer Y1 outputs an estimated value of thrust which is generated between the vibrating body 5 and the contact body 6.

The second output layer Y2 outputs an estimated value of a relative speed between the vibrating body 5 and the contact body 6. The third output layer Y3 outputs an estimated value of a resonant frequency of the vibrating body 5.

The upthrust vibration amplitude controller 30 controls the frequencies of the first alternating-current signal VA and the second alternating-current signal VB based on a value that is based on the amplitude of a signal obtained by adding the first current signal IA and the second current signal IB detected by the amplitude detection unit 18 and an estimated value of the resonant frequency output from the output layer Y3.

FIG. 12B is a diagram illustrating a second example of the configuration of the vibration-type drive device 102 according to the second exemplary embodiment. Elements similar to the elements illustrated in FIG. 12A are assigned the same reference numbers. For conciseness, the detailed description thereof is incorporated here by reference.

The NN 39 in the example of FIG. 12B has performed preliminarily learning and configured to output estimated values of the thrust, the speed, and the temperature of the vibrating body 5 from the output layers Y1 to Y3, respectively.

The upthrust vibration amplitude controller 30 controls a frequency command for the alternating-current signal VA according to an output signal of the amplitude detection unit 18 in such a manner that an output signal of the amplitude detection unit 18 equivalent to the amplitude in the upthrust vibration mode of the vibrating body 5 becomes a predetermined value.

The thrust and speed controller 21 outputs a phase difference command for setting the phase difference between the alternating-current signal VA and the alternating-current signal VB according to a difference between a speed command received from the command unit and an estimated speed and the estimated thrust, and adjusts the rate of change of an operation amount of the phase difference according to the estimated temperature output from the output layer Y3. Since, as the temperature of the vibrating body 5 increases, the efficiency of the vibration-type actuator 100 decreases, the thrust and speed controller 21 performs adjustment such as suppressing thrust when the temperature of the vibrating body 5 increases.

As described above, the first input layer X1 receives, as an input, a value that is based on the frequencies of the first alternating-current signal VA and the second alternating-current signal VB. The second input layer X2 receives, as an input, a value that is based on a phase difference between the first alternating-current signal VA and the second alternating-current signal VB.

The third input layer X3 receives, as an input, a value that is based on the amplitude of the first current signal IA. The fourth input layer X4 receives, as an input, a value that is based on the amplitude of the second current signal IB. The fifth input layer X5 receives, as an input, a value that is based on the amplitude of a signal obtained by adding the first current signal IA and the second current signal IB.

The first output layer Y1 outputs an estimated value of thrust which is generated between the vibrating body 5 and the contact body 6.

The second output layer Y2 outputs an estimated value of a relative speed between the vibrating body 5 and the contact body 6. The third output layer Y3 outputs an estimated value of a temperature of the vibrating body 5.

The thrust and speed controller 21 controls the phase difference between the first alternating-current signal VA and the second alternating-current signal VB based on the estimated value of the thrust output from the output layer Y1, the estimated value of the relative speed output from the output layer Y2, and the estimated value of the temperature output from the output layer Y3.

The upthrust vibration amplitude controller 30 controls the frequencies of the first alternating-current signal VA and the second alternating-current signal VB based on a value that is based on the amplitude of a signal obtained by adding the first current signal IA and the second current signal IB detected by the amplitude detection unit 18.

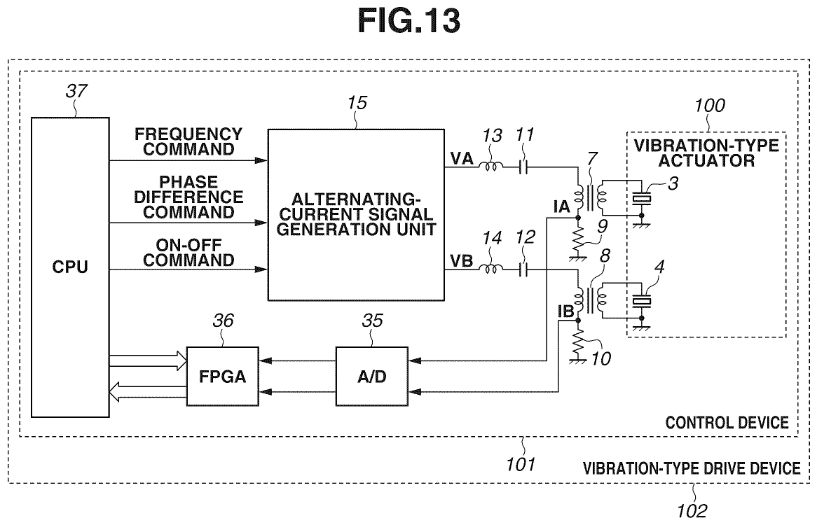

FIG. 13 is a diagram illustrating a third example of the configuration of the vibration-type drive device 102 according to the second exemplary embodiment. In the configuration illustrated in FIG. 13, the CPU 37 controls the NN 39 and the generating of a phase difference command and a frequency command illustrated in FIG. 12A. Elements similar to the elements illustrated in FIG. 12A are assigned the same reference numbers. For conciseness, the detailed description thereof is incorporated here by reference.

An analog-to-digital (A/D) converter 35 converts the current signal IA and the current signal IB from analog signals into digital signals. A field-programmable gate array (FPGA) 36 receives, as inputs, the digital signals IA and IB output from the A/D converter 35, detects the respective amplitudes of the signals IA and IB and an amplitude of a signal obtained by adding the signal IA and the signal IB, and outputs the detected amplitudes to the CPU 37. The FPGA 36 includes, a band-pass filter which, before detection of the respective amplitudes, removes a harmonic component and a direct-current component included in each of the signal IA and the signal IB.

The CPU 37 obtains estimated values of the thrust, the resonant frequency of the vibrating body 5, and the temperature of the vibrating body 5 from the amplitudes of the signals IA and IB and a signal obtained by adding the signals IA and IB output from the FPGA 36, the phase difference command, and the frequency command with use of an arithmetic routine for performing an arithmetic operation similar to that in the NN 39 illustrated in FIG. 12A.

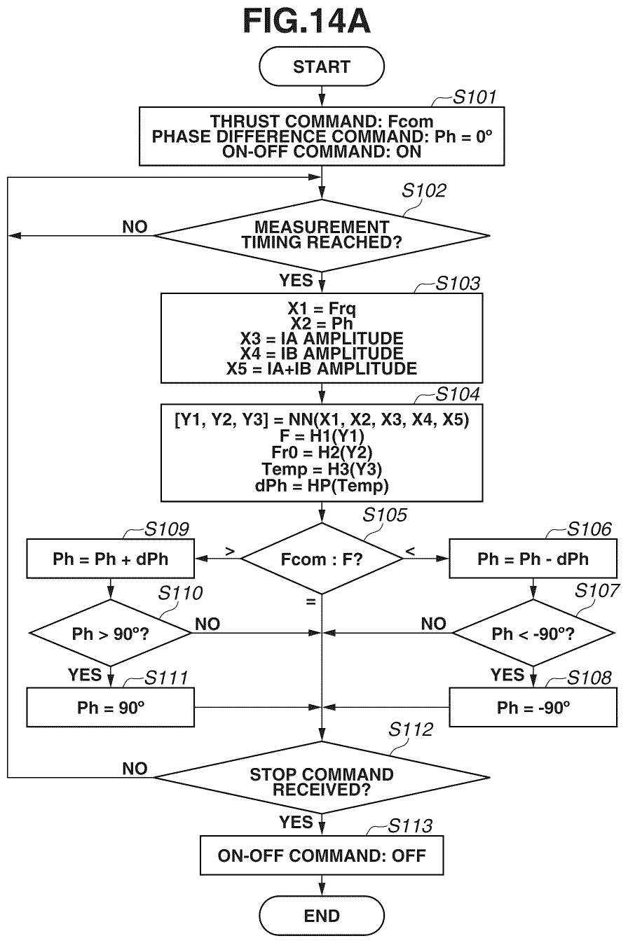

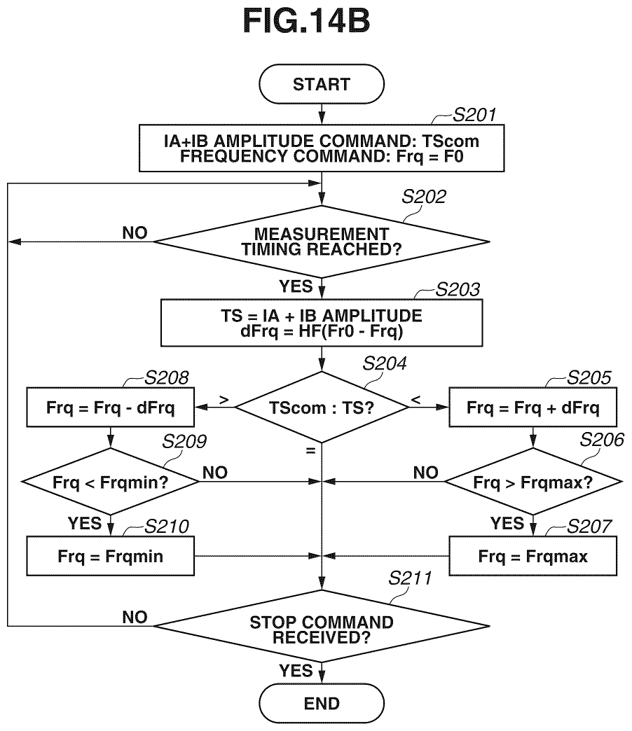

FIGS. 14A and 14B are flowcharts illustrating an operation in which the CPU 37 operates the phase difference command and the frequency command. FIG. 14A illustrates processing including control steps for controlling thrust. FIG. 14B illustrates processing including control steps for controlling the upthrust vibration amplitude.

In step S101 of FIG. 14A, the CPU 37 sets a previously determined thrust command Fcom, sets a phase difference command Ph to an initial phase difference of 0°, and sets an ON-OFF command to ON.

In step S102, the CPU 37 determines whether a measurement timing has been reached. If it is determined that the measurement timing has not yet been reached (NO in step S102), the CPU 37 waits in step S102. On the other hand, if it is determined that the measurement timing has been reached (YES in step S102), the CPU 37 advances the processing to step S103.

In step S103, the CPU 37 sets values to the input layers X1 to X5 of the neural network. The CPU 37 sets a frequency command Frq to the input layer X1, sets the phase difference command Ph to the input layer X2, sets the amplitude of the current signal IA to the input layer X3, sets the amplitude of the current signal IB to the input layer X4, and sets the amplitude of a signal obtained by adding the current signal IA and the current signal IB to the input layer X5. The frequency command Frq is set in a control routine for upthrust vibration amplitude, as described in FIG. 14B. The control routine for upthrust vibration amplitude is performed in parallel with a control routine for thrust illustrated in FIG. 14A.

In step S104, the CPU 37 obtains estimated values of thrust F, resonant frequency Fr0 of the vibrating body 5, and temperature Temp of the vibrating body 5 with use of an arithmetic routine for the trained neural network according to the values for the input layers X1 to X5 set in step S103. Then, the CPU 37 sets a minimum amount of change dPh of the phase difference command according to the temperature Temp. In subsequent steps, the CPU 37 compares the above-mentioned thrust command Fcom with the thrust F calculated in step S104 with each other to perform control of the phase difference command Ph.

Control of the phase difference command Ph is described with reference to step S105 to step S111.

In step S105, the CPU 37 compares the thrust command Fcom set in step S101 with the thrust F calculated in step S104.

If, as a result of comparison in step S105, it is determined that the thrust command Fcom is less than the thrust F (<in step S105), the CPU 37 advances the processing to step S106.

In step S106, the CPU 37 subtracts the minimum amount of change dPh from the phase difference command Ph as a new phase difference command Ph.

After the subtracting in step S106, in step S107, the CPU 37 determines whether the phase difference command Ph is less than or equal to −90°.

If, in step S107, it is determined that the phase difference command Ph is less than −90° (YES in step S107), the CPU 37 advances the processing to step S108.

On the other hand, if it is determined that the phase difference command Ph is not less than −90° (NO in step S107), the CPU 37 advances the processing to step S112.

In step S108, the CPU 37 sets the phase difference command Ph to −90°, and then advances the processing to step S112.

If, as a result of comparison in step S105, it is determined that the thrust command Fcom is greater than or equal to the thrust F (>in step S105), the CPU 37 advances the processing to step S109.

In step S109, the CPU 37 adds the minimum amount of change dPh to the phase difference command Ph to obtain a new phase difference command Ph.

In step S110, the CPU 37 determines whether the phase difference command Ph is greater than or equal to +90°.

If, as a result of comparison in step S110, it is determined that the phase difference command Ph is greater than or equal to +90° (YES in step S110), the CPU 37 advances the processing to step S111.

On the other hand, if, as a result of comparison in step S110, it is determined that the phase difference command Ph is less than +90° (NO in step S110), the CPU 37 advances the processing to step S112.

In step S111, the CPU 37 sets the phase difference command Ph to +90°, and then advances the processing to step S112.

In a case where the processing operation in step S108 ends, in case where the processing operation in step S111 ends, or if, as a result of comparison in step S105, it is determined that the thrust command Fcom and the thrust F are equal to each other (=in step S105), the CPU 37 advances the processing to step S112. By repeating the processing operations in step S105 to step S111, the phase difference command Ph is controlled in such a manner that the thrust F comes close to the thrust command Fcom.

In step S112, the CPU 37 determines whether a stop command has been input. If, in step S112, it is determined that the stop command has not yet been input (NO in step S112), the CPU 37 returns the processing to step S102.

If it is determined that the stop command has been input (YES in step S112), the CPU 37 advances the processing to step S113.

In step S113, the CPU 37 sets the ON-OFF command to OFF. With this setting, the outputs of the alternating-current signal VA and the alternating-current signal VB output by the alternating-current signal generation unit 15 become 0 volts (V), and the contact body (slider) 6 of the vibration-type actuator 100 stops.

Then, when the processing operation in step S113 ends, the process illustrated in FIG. 14A ends.

In step S201 of FIG. 14B, the CPU 37 sets a previously determined upthrust vibration amplitude command TScom, and sets a frequency command Frq to an initial frequency F0.

In step S202, the CPU 37 determines whether a measurement timing has been reached. If it is determined that the measurement timing has not yet been reached (NO in step S202), the CPU 37 waits in step S202.

If it is determined that the measurement timing has been reached (YES in step S202), the CPU 37 advances the processing to step S203.

In step S203, the CPU 37 acquires, from the FPGA 36, an upthrust vibration amplitude TS, which is the amplitude of a signal obtained by adding the current signal IA and the current signal IB. Then, the CPU 37 sets a minimum amount of change dFrq of the frequency command according to a difference between the frequency command Frq and the resonant frequency Fr0 of the vibrating body 5 obtained in step S104 illustrated in FIG. 14A.

Then, in subsequent steps, the CPU 37 compares the upthrust vibration amplitude command TScom with the upthrust vibration amplitude TS detected in step S203, and performs control of the frequency command Frq.

The control of the frequency command Frq is described with reference to step S204 to step S210.

In step S204, the CPU 37 compares the upthrust vibration amplitude command TScom set in step S201 with the upthrust vibration amplitude TS detected in step S203.

If, as a result of comparison in step S204, it is determined that the upthrust vibration amplitude command TScom is less than the upthrust vibration amplitude TS (<in step S204), the CPU 37 advances the processing to step S205.

In step S205, the CPU 37 adds the minimum amount of change dFrq to the frequency command Frq to obtain a new frequency command Frq.

In step S206, the CPU 37 determines whether the frequency command Frq is greater than or equal to a maximum frequency command Frqmax.

If it is determined that the frequency command Frq is greater than or equal to the maximum frequency command Frqmax (YES in step S206), the CPU 37 advances the processing to step S207.

On the other hand if it is determined that the frequency command Frq is not less than the maximum frequency command Frqmax (NO in step S206), the CPU 37 advances the processing to step S211.

In step S207, the CPU 37 sets the frequency command Frq to the maximum frequency command Frqmax, and then advances the processing to step S211.

If, as a result of comparison in step S204, it is determined that the upthrust vibration amplitude command TScom is greater than the upthrust vibration amplitude TS (>in step S204), the CPU 37 advances the processing to step S208.

In step S208, the CPU 37 subtracts the minimum amount of change dFrq from the frequency command Frq to obtain a new frequency command Frq.

In step S209, the CPU 37 determines whether the frequency command Frq is less than a minimum frequency command Frqmin.

If it is determined that the frequency command Frq is less than the minimum frequency command Frqmin (YES in step S209), the CPU 37 advances the processing to step S210.

On the other hand, if it is determined that the frequency command Frq is greater than or equal to the minimum frequency command Frqmin (NO in step S209), the CPU 37 advances the processing to step S211.

In step S210, the CPU 37 sets the frequency command Frq to the minimum frequency command Frqmin, and then advances the processing to step S211.

In a case where the processing operation in step S207 ends, in case where the processing operation in step S210 ends, or if, as a result of comparison in step S204, it is determined that the upthrust vibration amplitude command TScom and the upthrust vibration amplitude TS are equal to each other (=in step S204), the CPU 37 advances the processing to step S211. By repeating the processing operations in step S204 to step S210, the frequency command Frq is controlled in such a manner that the upthrust vibration amplitude TS comes close to the upthrust vibration amplitude command TScom.

In step S211, the CPU 37 determines whether a stop command has been input. If, in step S211, it is determined that the stop command has not yet been input (NO in step S211), the CPU 37 returns the processing to step S202, thus performing processing operations in step S202 and subsequent steps.

If, in step S211, it is determined that the stop command has been input (YES in step S211), the processing in the flowchart illustrated in FIG. 14B ends.

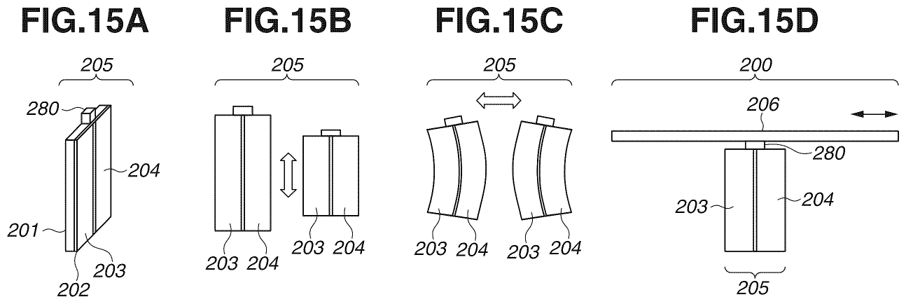

FIGS. 15A, 15B, 15C, and 15D are diagrams illustrating examples of configurations of the vibration-type actuator 200. The configuration and operating principle of the vibration-type actuator 200 according to the second exemplary embodiment are described with reference to FIGS. 15A to 15D.

The vibration-type actuator 200 according to the second exemplary embodiment is configured to include, as illustrated in FIG. 15D, a vibrating body 205 and a contact body 206. The vibrating body 205 is a plate-like vibrating body made from a conductive material, and is configured with, as illustrated in FIG. 15A and FIG. 15D, a piezoelectric element 202 and an elastic body 201, which has, on the plate-like surface thereof, a projection portion 280 which is in contact with the contact body 206. The piezoelectric element 202 constitutes a part of the vibrating body 205, and is a component portion for causing the vibrating body 205 to vibrate.

Moreover, on the surface of the piezoelectric element 202, as illustrated in FIG. 15A, two electrodes 203 and 204 are formed. The two electrodes 203 and 204 are made to be electrodes the space between which is electrically insulated, and two alternating-current voltages the phase of each of which is able to independently change are applied to the two electrodes 203 and 204. Moreover, the entire surface of the reverse side of the piezoelectric element 202 is made to be an electrode, and is configured to allow the ground potential to be connected thereto from the opposite side of the piezoelectric element 202 through a via (hole) provided in a part of the piezoelectric element 202. In the following description, the electrodes 203 and 204 are referred to as a “piezoelectric body 203” and a “piezoelectric body 204”, respectively.

The contact body 206 illustrated in FIG. 15D is a slider which is in pressed contact with the projection portion 280 of the vibrating body 205 at a fixed pressure force by a pressure mechanism. The contact body (slider) 206 is configured to be relatively moved in directions indicated by a double-headed arrow in FIG. 15D by vibrations excited by the vibrating body 205.

FIGS. 15B and 15C are diagrams illustrating examples of vibration modes of the vibrating body 205.

FIG. 15B illustrates the vibration shape (stretching vibration) of a vibration mode which is excited by the vibrating body 205 when alternating-current voltages which are identical in amplitude and phase are applied to the piezoelectric body 203 and the piezoelectric body 204 (an upthrust vibration mode).

Moreover, FIG. 15C illustrates the vibration shape (bending vibration) of a vibration mode which is excited by the vibrating body 205 when alternating-current voltages which are identical in amplitude and opposite in phase are applied to the piezoelectric body 203 and the piezoelectric body 204 (an advancing vibration mode).

Thus, when the phase difference between alternating-current voltages which are applied to the piezoelectric body 203 and the piezoelectric body 204 of the vibrating body 205 is set to 0°, a vibration in the vibration mode illustrated in FIG. 15B (upthrust vibration mode) is excited. Moreover, when the phase difference between alternating-current voltages which are applied to the piezoelectric body 203 and the piezoelectric body 204 of the vibrating body 205 is set to 180°, a vibration in the vibration mode illustrated in FIG. 15C (advancing vibration mode) is excited.

Additionally, when the phase difference between alternating-current voltages which are applied to the piezoelectric body 203 and the piezoelectric body 204 of the vibrating body 205 is set to a phase difference other than 0° and 180° (in actuality, about a range of ±120° from 0° being used), both the vibration modes illustrated in FIGS. 15B and 15C are simultaneously excited. In this case, the contact body (slider) 206, which is in pressed contact with the projection portion 280 provided in the vibrating body 205, moves in the transverse direction of a rectangle of the vibrating body 205. Then, as the phase difference is more away from 0°, the amplitude in the vibration mode illustrated in FIG. 15C (advancing vibration mode) becomes larger, so that the relative speed between the contact body (slider) 206 and the vibrating body 205 increases.

If the piezoelectric body 203 and the piezoelectric body 204 are replaced with the above-mentioned piezoelectric bodies 3 and 4, the vibration-type drive device 102 according to the above-described first exemplary embodiment can be applied.

While, in the above-described example, the amplitude of a difference signal between the current signal IA and the current signal IB is set as an upthrust vibration amplitude, depending on a structure of the vibration-type actuator, the amplitude of a difference signal between the current signal IA and the current signal IB may be set as an upthrust vibration amplitude.

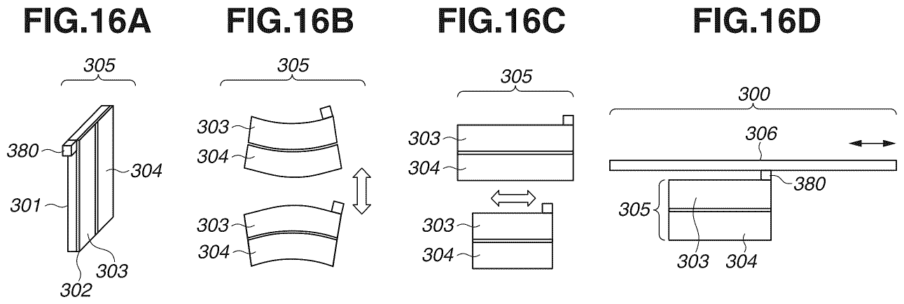

FIGS. 16A, 16B, 16C, and 16D are diagrams illustrating configurations of a vibration-type actuator 300. The vibration-type actuator 300 uses the same vibration modes as those in the vibration-type actuator 200, but differs from the vibration-type actuator 200 in the position of a projection portion 380 which is in contact with a contact body 306 and in that the amplitude of “the current signal IA−the current signal IB” corresponds to the upthrust vibration amplitude.

The vibration-type actuator 300 is configured to include, as illustrated in FIG. 16D, a vibrating body 305 and the contact body 306. The vibrating body 305 is configured with, as illustrated in FIG. 16A and FIG. 16D, a piezoelectric element 302 and an elastic body 301, which has, on the plate-like surface thereof, the projection portion 380 which is in contact with the contact body 306. The piezoelectric element 302 constitutes a part of the vibrating body 305, and is a component portion for causing the vibrating body 305 to vibrate. Moreover, on the surface of the piezoelectric element 302, as illustrated in FIG. 16A, two electrodes 303 and 304 are formed. In the following description, the electrodes 303 and 304 are referred to as a piezoelectric body 303 and a piezoelectric body 304, respectively.

FIGS. 16B and 16C are diagrams illustrating examples of vibration modes of the vibrating body 305.

FIG. 16B illustrates the vibration shape (bending vibration) of a vibration mode which is excited by the vibrating body 305 when alternating-current voltages which are identical in amplitude and opposite in phase are applied to the piezoelectric body 303 and the piezoelectric body 304 (an upthrust vibration mode). FIG. 16C illustrates the vibration shape (stretching vibration) of a vibration mode which is excited by the vibrating body 305 when alternating-current voltages which are identical in amplitude and phase are applied to the piezoelectric body 303 and the piezoelectric body 304 (an advancing vibration mode).

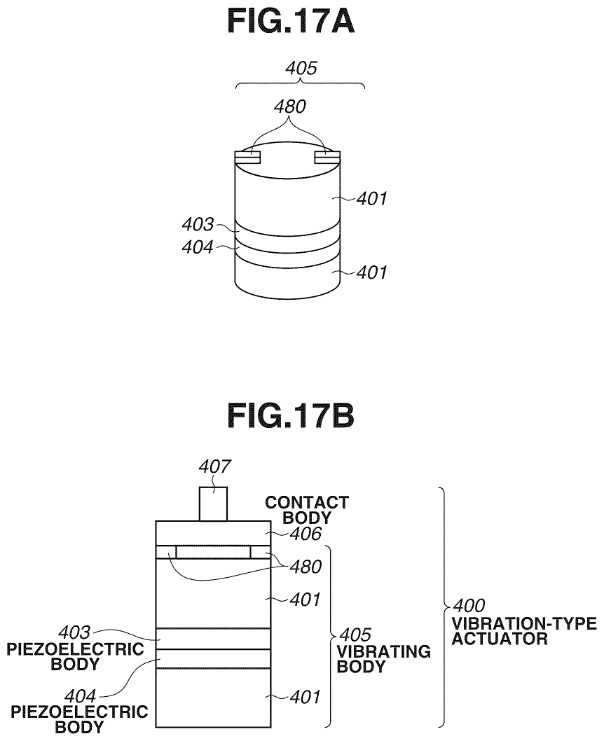

FIGS. 17A and 17B are diagrams illustrating an example of a configuration of a vibration-type actuator 400 according to a third exemplary embodiment. The configuration and operating principle of the vibration-type actuator 400 according to the third exemplary embodiment are described with reference to FIGS. 17A and 17B.

The vibration-type actuator 400 according to the third exemplary embodiment is configured to include, as illustrated in FIG. 17B, a vibrating body 405, a contact body 406, and a rotational shaft 407 connected to the contact body 406.

As illustrated in FIG. 17A, the vibrating body 405 is a cylindrical vibrating body made from a conductive material, and is configured with a piezoelectric body 403, a piezoelectric body 404, and elastic bodies 401, which sandwich the piezoelectric body 403 and the piezoelectric body 404 and have projection portions 480 on the upper portion of the cylinder of the vibrating body 405.

Moreover, the piezoelectric body 403 is a component portion which adds a vibration for elongating and contracting the vibrating body 405 in the direction of the height of the cylinder of the vibrating body 405, the piezoelectric body 404 is a component portion which adds a torsional vibration to the vibrating body 405 toward the central axis of the cylinder of the vibrating body 405, and the piezoelectric body 403 and the piezoelectric body 404 are sandwiched and fixed between the elastic bodies 401 by a clamping member.

The contact body 406 illustrated in FIG. 17B may be a rotor which is in pressed contact with the projection portions 480 of the vibrating body 405 at a fixed pressure force by a pressure mechanism. The contact body (rotor) 406 is rotated by a vibration which is excited at the vibrating body 405, thus rotating the rotational shaft 407 together with the contact body (rotor) 406.

The driving operation of the vibration-type actuator 400 is described herein. The vibration-type actuator 400 is an actuator which rotationally drives the contact body (rotor) 406 by a composite vibration composed of a stretching vibration (upthrust vibration) and a torsional vibration (advancing vibration) which are excited at the vibrating body 405.

When an alternating-current voltage with a predetermined frequency is applied to the piezoelectric body 403, a stretching vibration (upthrust vibration) is excited at the vibrating body 405, and, when an alternating-current voltage is applied to the piezoelectric body 404, a torsional vibration (advancing vibration) is excited at the vibrating body 405. Therefore, when the stretching vibration (upthrust vibration) and the torsional vibration (advancing vibration) are excited with the phases thereof being temporally shifted from each other, the contact body (rotor) 406 rotates.

Differences between the vibration-type actuator 400 and the vibration-type actuator 100 are described herein. Between these actuators, in addition to a difference in shape, there is a large difference in driving. This difference is that, while the vibration-type actuator 100 excites an upthrust vibration by an in-phase component of applied two-phase alternating-current voltages and excites an advancing vibration by an opposite-phase component thereof, each phase of the two-phase alternating-current voltages is individually associated with the upthrust vibration and the advancing vibration.

Therefore, while the vibration-type actuator 100 controls the amplitude balance of an upthrust vibration and an advancing vibration by a phase difference between the applied two-phase alternating-current voltages, in the case of the vibration-type actuator 400, even if the phase difference is operated, the amplitude balance of an upthrust vibration and an advancing vibration does not change. Therefore, the vibration-type actuator 400 controls the amplitude balance of an upthrust vibration and an advancing vibration by operating the amplitude balance of two-phase alternating-current voltages or the voltage amplitude of one of the two phases.

The vibration excitation to the vibrating body 405 attributable to an external force of the vibration-type actuator 400 is described herein. An example in which driving is performed on the condition that the frequencies of the two-phase alternating-current voltages are higher than the natural frequency in the upthrust vibration mode of the vibrating body 405 is described. Even in the vibration-type actuator 400, the second vibrational component is superposed on the vibrating body 405 by a force which is generated at a contact portion according to the relative speed and relative force between the projection portions 480 and the contact body (rotor) 406.

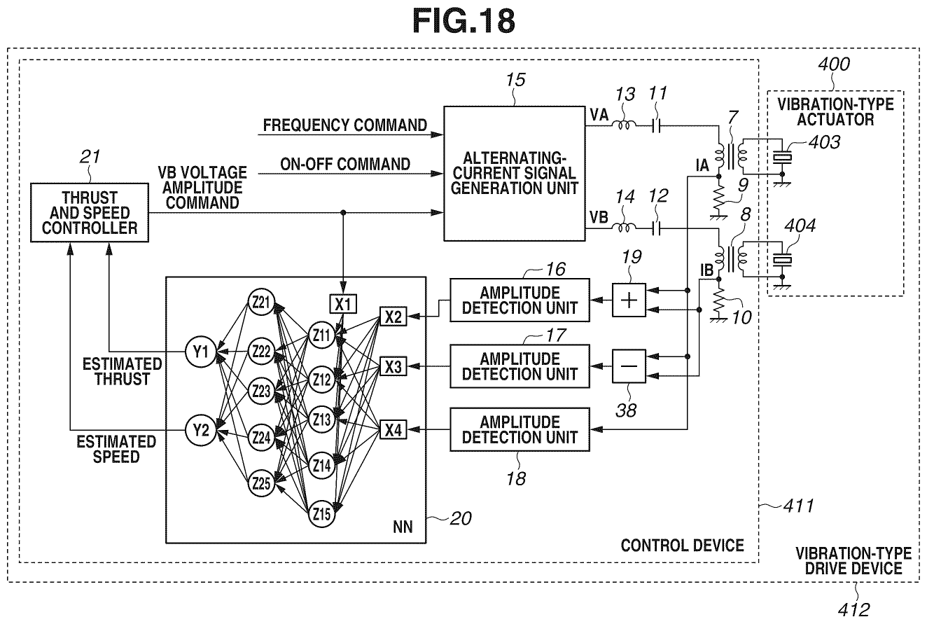

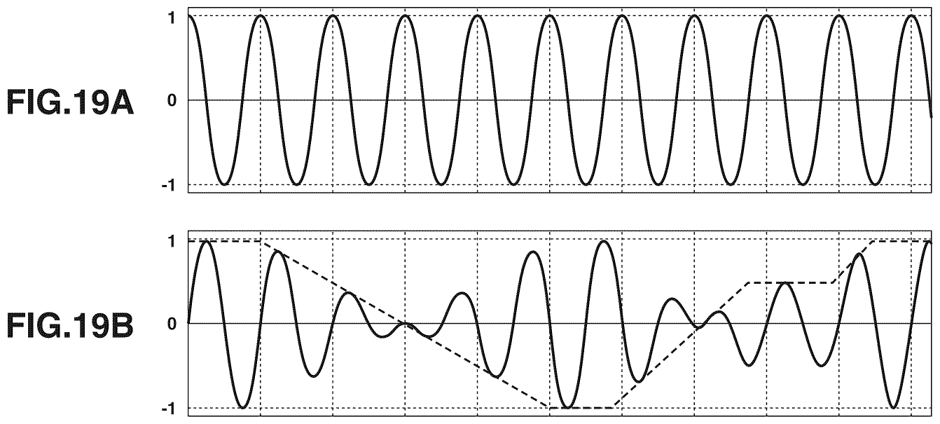

FIG. 18 is a diagram illustrating a configuration of a vibration-type drive device 412 according to the third exemplary embodiment. The vibration-type drive device 412 includes the vibration-type actuator 400 and a control device 411 for the vibration-type actuator 400.

The control device 411 includes transformers 7 and 8, resistors 9 and 10, capacitors 11 and 12, inductors 13 and 14, an alternating-current signal generation unit 15, amplitude detection units 16 to 18, an adder 19, a NN 20, a thrust and speed controller 21, and a subtractor 38.

The generation unit for alternating-current voltages is described herein. The alternating-current signal generation unit 15 generates two-phase alternating-current signal (first signal) VA and alternating-current signal (second signal) VB different in phase by 90° based on a frequency command which is output from the command unit and a VB voltage amplitude command which is output from the thrust and speed controller 21. The alternating-current signal generation unit 15 sets the alternating-current signal VA to a predetermined amplitude and sets the alternating-current signal VB to an amplitude corresponding to the VB voltage amplitude command. In a case where the VB voltage amplitude command is a negative value, the alternating-current signal generation unit 15 inverts the alternating-current signal VB between positive and negative and outputs the inverted alternating-current signal VB.

As described above, the first input layer X1 receives, as an input, a value that is based on the amplitude of the second alternating-current signal VB. The second input layer X2 receives, as an input, a value that is based on the amplitude of a signal obtained by adding the first current signal IA and the second current signal IB. The third input layer X3 receives, as an input, a value that is based on the amplitude of a signal obtained by subtracting the second current signal IB from the first current signal IA. The fourth input layer X4 receives, as an input, a value that is based on the amplitude of the first current signal IA.

The first output layer Y1 outputs an estimated value of thrust occurring between the vibrating body 405 and the contact body 406.

The second output layer Y2 outputs an estimated value of a relative speed between the vibrating body 405 and the contact body 406.

The thrust and speed controller 21 controls the amplitude of the second alternating-current signal VB based on an estimated value of the thrust output from the first output layer Y1 and an estimated value of the relative speed output from the second output layer Y2.

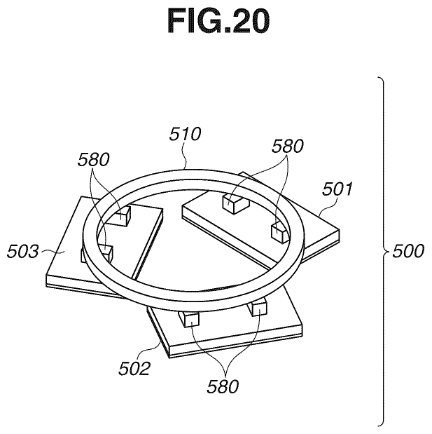

FIGS. 19A and 19B are diagrams illustrating examples of waveforms of the alternating-current signal VA, the alternating-current signal VB, and the VB voltage amplitude command. FIG. 19A illustrates a signal waveform of the alternating-current signal VA. FIG. 19B illustrates signal waveforms of the alternating-current signal VB (solid line) and the VB voltage amplitude command (dashed line). The alternating-current signal VB is shifted in phase by 90° relative to the alternating-current signal VA, and the sign of a phase difference between the alternating-current signal VA and the alternating-current signal VB is switched by the sign of the VB voltage amplitude command.

Referring to FIG. 18, the alternating-current signal VA and the alternating-current signal VB are connected to the primary side winding wires of the transformer 7 and the transformer 8 via series resonance circuits composed of the inductors 13 and 14 and the capacitors 11 and 12, respectively. The voltages input to the primary side winding wires of the transformer 7 and the transformer 8 are boosted, and are then applied, as a first drive voltage and a second drive voltage, to the piezoelectric body 403 and the piezoelectric body 404 of the vibration-type actuator 400 connected to the secondary side winding wires of the transformer 7 and the transformer 8.

The inductor values of the secondary side winding wires of the transformer 7 and the transformer 8 are frequency-matched with the braking capacities of the piezoelectric body 403 and the piezoelectric body 404. This causes currents approximately proportional to the vibration speeds of distortions occurring in the piezoelectric body 403 and the piezoelectric body 404 to flow through the primary side winding wires of the transformer 7 and the transformer 8.

On the other hand, the resistors 9 and 10 are connected in series to the primary side winding wires of the transformer 7 and the transformer 8. The resistors 9 and 10 convert currents flowing through the primary side winding wires of the connected transformers 7 and 8 into voltages, thus generating a current signal IA and a current signal IB. The current signal IA is a signal associated with the vibration in the stretching vibration mode (upthrust vibration mode) of the vibrating body 405, and the current signal IB is a signal associated with the torsional vibration mode (advancing vibration mode) of the vibrating body 405.

A configuration related to the estimation and control of thrust and speed is described herein. To detect the amplitude of the upthrust vibration of the vibration-type actuator 100 illustrated in FIG. 2, the amplitude of the current signal IA+the current signal IB is detected. In the case of the vibration-type actuator 400, the amplitude of the current signal IA is equivalent to the amplitude of the upthrust vibration.

In the third exemplary embodiment, instead of the amplitude of the current signal IA illustrated in FIG. 2, the amplitude of the current signal IA+the current signal IB is detected. Instead of the amplitude of the current signal IB illustrated in FIG. 2, the amplitude of the current signal IA−the current signal IB is detected. Instead of the amplitude of the current signal IA+the current signal IB illustrated in FIG. 2, the amplitude of the current signal IA is detected.

The amplitude detection unit 16 receives, as an input, a signal obtained by adding the current signal IA and the current signal IB, which the adder 19 outputs, and outputs the amplitude of the signal obtained by adding the current signal IA and the current signal IB to the input layer X2.

The amplitude detection unit 17 receives, as an input, a signal obtained by subtracting the current signal IB from the current signal IA, which the subtractor 38 outputs, and outputs the amplitude of the signal obtained by subtracting the current signal IB from the current signal IA to the input layer X3.

The amplitude detection unit 18 outputs the amplitude of the current signal IA to the input layer X4.

These amplitudes are changed by the second vibrational component, which is superposed on the vibrating body 405 according to the thrust and speed, and estimated values of the thrust and speed are output by the NN 20, which has been caused to perform learning with inputting of the VB voltage amplitude command and the amplitude values which the amplitude detection units 16 to 18 output.

Then, the estimated thrust and the estimated speed, which are arithmetic results obtained by the NN 20, are input to the thrust and speed controller 21. Then, the thrust and speed controller 21 outputs a VB voltage amplitude command signal, which is used to set the voltage amplitude of the alternating-current signal VB, to the alternating-current signal generation unit 15 according to a difference between a speed command received from the command unit and the estimated speed and the estimated thrust. Then, the alternating-current signal generation unit 15 sets the voltage amplitude of the alternating-current signal VB, so that the speed and thrust are controlled according to the amplitude of the vibration in the advancing vibration mode excited at the vibrating body 405.

FIG. 20 is a diagram illustrating a configuration of a vibration-type actuator 500 according to a fourth exemplary embodiment.

Vibrating bodies 501, 502, and 503, each of which corresponds to the vibrating body 5 illustrated in FIG. 1, are in contact with an annular contact body 510 at respective contact surfaces of projection portions 580 of the vibrating bodies 501, 502, and 503 along the circumference of the annular contact body 510. The thrusts of three vibrating bodies 501, 502, and 503 are added and the combined thrusts provides increased output torque of the vibration-type actuator 500.

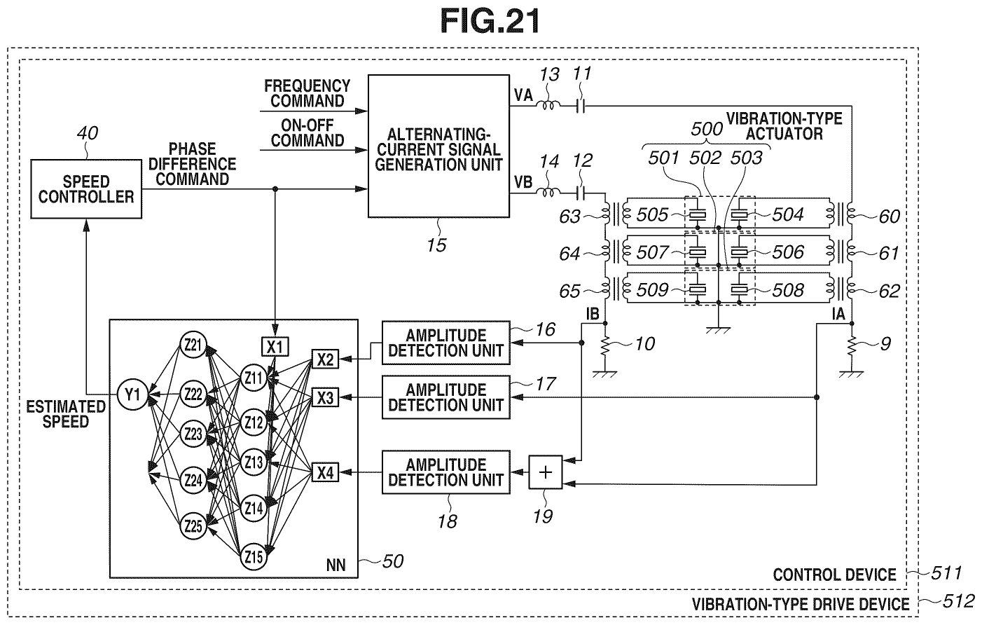

FIG. 21 is a diagram illustrating a configuration of a vibration-type drive device 512 according to the fourth exemplary embodiment. Elements similar to the elements illustrated in FIG. 2 are assigned the same reference numbers. For conciseness, the detailed description thereof is incorporated here by reference.

The vibration-type drive device 512 includes the vibration-type actuator 500 and a control device 511 for the vibration-type actuator 500.

The control device 511 includes resistors 9 and 10, capacitors 11 and 12, inductors 13 and 14, an alternating-current signal generation unit 15, amplitude detection units 16 to 18, an adder 19, a speed controller 40, an NN 50, and transformers 60 to 65.

The vibrating body 501 is provided with piezoelectric bodies 504 and 505 serving as piezoelectric bodies for vibration. The vibrating body 502 is provided with piezoelectric bodies 506 and 507 serving as piezoelectric bodies for vibration. The vibrating body 503 is provided with piezoelectric bodies 508 and 509 serving as piezoelectric bodies for vibration.

The respective piezoelectric bodies are divided into A-phase side piezoelectric bodies, which are connected to the alternating-current signal VA via the inductor 13, the capacitor 11, and the three transformers 60 to 62, and B-phase side piezoelectric bodies, which are connected to the alternating-current signal VB via the inductor 14, the capacitor 12, and the three transformers 63 to 65.

The A-phase side piezoelectric bodies include the piezoelectric bodies 504, 506, and 508, which are connected to the secondary side winging wires of the transformers 60, 61, and 62, respectively. The primary side winding wires of the transformers 60, 61, and 62 are connected in series, in which one end of the series connection is connected to the capacitor 11 and the other end thereof is connected to the resistor 9 for current detection.

On the other hand, the B-phase side piezoelectric bodies include the piezoelectric bodies 505, 507, and 509, which are connected to the secondary side winging wires of the transformers 63, 64, and 65, respectively. The primary side winding wires of the transformers 63, 64, and 65 are connected in series, in which one end of the series connection is connected to the capacitor 12 and the other end thereof is connected to the resistor 10 for current detection.

The resistor 9 is used to detect the current signal IA corresponding to the vibration speed of the A-phase side piezoelectric bodies, and the resistor 10 is used to detect the current signal IB corresponding to the vibration speed of the B-phase side piezoelectric bodies.

Since the vibrating bodies 501, 502, and 503 are driven with series connection, when alternating-current voltages are applied to the primary side winding wires of the transformers, substantially uniform vibrations are formed. Moreover, the second vibrational components, which are superposed on the respective vibrating bodies by vibrations caused by frictional force acting between the projection portions 580 of the vibrating bodies 501, 502, and 503 and the contact body (rotor) 510, also change well uniformly. Since the vibrations of the vibrating bodies 501, 502, and 503 are well uniform, as with the first exemplary embodiment, detecting the current signals IA and IB on the primary side winding wires of the transformers enables detecting vibrations of the vibrating bodies 501, 502, and 503 as a single vibration.

Thus, even in the fourth exemplary embodiment, in which the vibrating bodies 501, 502, and 503 are plurally connected in series to be driven, the NN 20 described in the first exemplary embodiment can be used to estimate the thrust and speed. In the fourth exemplary embodiment, the NN 50, which has been previously caused to perform learning in such a way as to estimate only the speed, is used to estimate the speed. The speed controller 40 compares the estimated speed with a speed command received from the command unit, and outputs a phase difference command for setting a phase difference between the alternating-current signal VA and the alternating-current signal VB in such a manner that the estimated speed becomes equal to the speed command.

While, in the fourth exemplary embodiment, an example in which a plurality of vibrating bodies 501, 502, and 503 are connected to the transformers 60 to 65 and are connected in series and voltages are applied to both ends of the plurality of vibrating bodies 501, 502, and 503 has been described, piezoelectric bodies of a plurality of vibrating bodies can be directly connected in series without via transformers. Moreover, while, in the above-mentioned example, vibrations are detected with the current signals IA and IB on the primary side wiring wires of the transformers, a piezoelectric element for vibration detection can be separately provided in a vibrating body.

As described herein, the first input layer X1 receives, as an input, a value that is based on a phase difference between the first alternating-current signal VA and the second alternating-current signal VB. The second input layer X2 receives, as an input, a value that is based on the amplitude of the second current signal IB. The third input layer X3 receives, as an input, a value that is based on the amplitude of the first current signal IA. The fourth input layer X4 receives, as an input, a value that is based on the amplitude of a signal obtained by adding the first current signal IA and the second current signal IB. The output layer Y1 outputs an estimated value of a relative speed between the vibrating bodies 501, 502, and 503 and the contact body 510.

The speed controller 40 controls a phase difference between the first alternating-current signal VA and the second alternating-current signal VB based on an estimated value of the relative speed output from the output layer Y1.

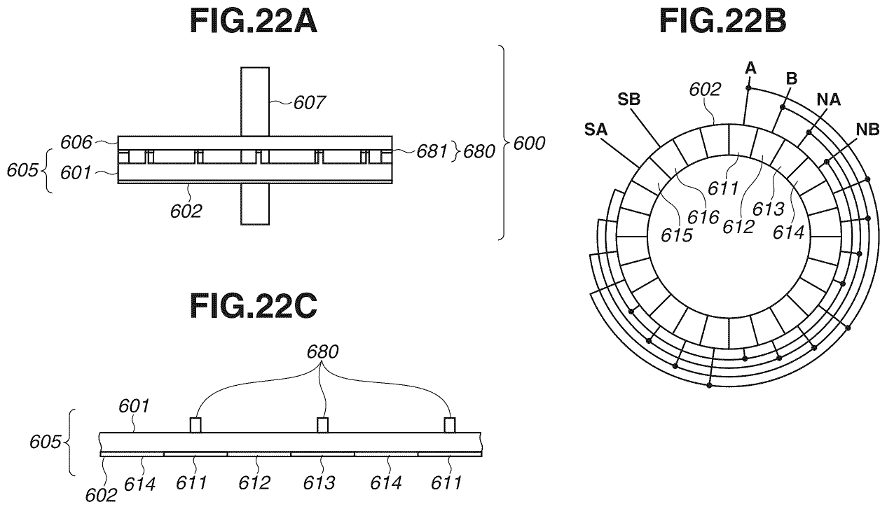

FIG. 22A is a diagram illustrating a configuration of a vibration-type actuator 600 according to a fifth exemplary embodiment.

The vibration-type actuator 600 according to the fifth exemplary embodiment includes a vibrating body 605, a contact body 606, which is an annular rotor, and a rotational shaft 607 connected to the contact body (rotor) 606. The vibrating body 605 is an annular vibrating body made from a conductive material, and is configured with a piezoelectric element 602 and an elastic body 601, which has, on a circular ring thereof, projection portions 680 which are in contact with the contact body (rotor) 606. Each of the projection portions 680 has a friction member 681 made from resin on a contact portion thereof with the contact body (rotor) 606. The piezoelectric element 602 constitutes a part of the vibrating body 605, and is a component portion for causing the vibrating body 605 to vibrate.

FIG. 22B is a diagram illustrating examples of a plurality of electrode structures and electrical wirings which are configured in the piezoelectric element 602 illustrated in FIG. 22A.

As illustrated in FIG. 22B, the piezoelectric element 602 is provided with 24 electrodes arranged at regular intervals on the circumference thereof. The respective electrodes of the piezoelectric element 602 are electrically connected by connection wirings for every 4 electrodes along the circumference. Here, regions of the piezoelectric element 602 in each of which a group of electrodes connected together is provided are referred to as piezoelectric bodies 611, piezoelectric bodies 612, piezoelectric bodies 613, and piezoelectric bodies 614, for respective connections.

The piezoelectric bodies 611 are arranged at intervals of 60° on the circumference, and, when an alternating-current voltage A is applied, an out-of-plane flexural vibration with 6 waves is formed along the circumference of the vibrating body 605. Additionally, when an alternating-current voltage B, an alternating-current voltage NA, and an alternating-current voltage NB which are each sequentially shifted from the alternating-current voltage A by every 90° are applied to the piezoelectric body 611, the piezoelectric body 612, and the piezoelectric body 613, respectively, an out-of-plane progressive vibrational wave with 6 waves is formed on the vibrating body 605. Then, the progressive vibrational wave with 6 waves causes a relative force to be generated between the projection portions 680 of the vibrating body 605 and the contact body (rotor) 606, thus rotating the contact body (rotor) 606.

Moreover, the piezoelectric element 602 is provided with a plurality of electrodes for vibration detection, and regions of the piezoelectric element 602 in which these electrodes are provided are referred to as a “piezoelectric body 615” and a “piezoelectric body 616”. The piezoelectric body 615 detects vibrations excited by the piezoelectric body 611 and the piezoelectric body 613 and thus outputs a vibration detection signal SA. The piezoelectric body 616 detects vibrations excited by the piezoelectric bodies 612 and the piezoelectric bodies 614 and thus outputs a vibration detection signal SB.

FIG. 22C is a diagram illustrating an example of a positional relationship between the piezoelectric bodies 611 to 614 and the projection portions 680. A projection portion 680 is provided at each center of electrode compartments of each piezoelectric body 611 and each piezoelectric body 613 to which the alternating-current voltage A and the alternating-current voltage NA are connected, respectively. When vibrations caused by the piezoelectric bodies 611 and the piezoelectric bodies 613 (referred to as a A-phase vibration) and vibrations caused by the piezoelectric bodies 612 and the piezoelectric bodies 614 (referred to as a B-phase vibration), the A-phase vibration excites an upthrust vibration for vibrating the projection portions 680 in the direction of upthrusting the contact body (rotor) 606 and the B-phase vibration excites an advancing vibration for vibrating the projection portions 680 in the direction of the projection portions 680 being tilted to cause the contact body (rotor) 606 to move relative to the elastic body 601.

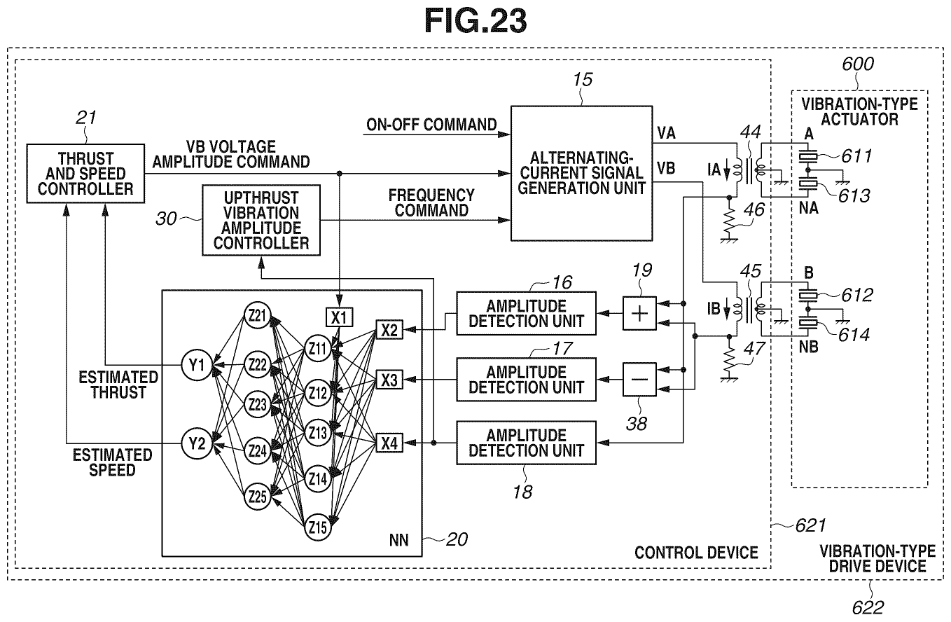

FIG. 23 is a diagram illustrating a configuration of a vibration-type drive device 622 according to the fifth exemplary embodiment. In FIG. 23, constitute elements similar to the constitute elements illustrated in FIG. 18 are assigned the same reference characters as in FIG. 18, and the detailed description thereof is incorporated by reference here.

The vibration-type drive device 622 includes the vibration-type actuator 600 and a control device 621 for the vibration-type actuator 600.

The control device 621 includes an alternating-current signal generation unit 15, amplitude detection units 16 to 18, an adder 19, an NN 20, a thrust and speed controller 21, an upthrust vibration amplitude controller 30, a subtractor 38, transformers 44 and 45, and resistors 46 and 47.

The vibration-type actuator 600 is driven at four-phase alternating-current voltages.

The alternating-current voltage A and the alternating-current voltage NA, as well as the alternating-current voltage B and the alternating-current voltage NB, are set as opposite-phase alternating-current voltages, the phases of which are opposite each other. Paired piezoelectric bodies 611 and 613 and paired piezoelectric bodies 612 and 614, to which opposite-phase alternating-current voltages are applied, are connected to the secondary side winding wires with a center tap of the transformers 44 and 45, respectively.

The alternating-current signal VA and the alternating-current signal VB, which are outputs of the alternating-current signal generation unit 15, are applied to respective ends of the primary side winding wires of the transformers 44 and 45, and to respective other ends of transformers 44 and 45 are connected to the resistors 46 and 47 for current detection.

The resistor 46 and the resistor 47 are used to detect the current signal IA and the current signal IB. The amplitude detection unit 16 outputs the amplitude of a signal obtained by adding the current signal IA and the current signal IB, which the adder 19 outputs, to the input layer X2. The amplitude detection unit 17 outputs the amplitude of a signal obtained by subtracting the current signal IB from the current signal IA, which the subtractor 38 outputs, to the input layer X3. The amplitude detection unit 18 outputs the amplitude of the current signal IA to the input layer X4 and the upthrust vibration amplitude controller 30. The NN 20 outputs an estimated thrust and an estimated speed from the output layers Y1 and Y2, respectively.

The thrust and speed controller 21 outputs a VB voltage amplitude command signal, which is used to set the voltage amplitude of the alternating-current signal VB, to the alternating-current signal generation unit 15 according to a difference between a speed command received from the command unit and the estimated speed and the estimated thrust. The alternating-current signal generation unit 15 sets the voltage amplitude of the alternating-current signal VB, so that the speed and thrust are controlled according to the magnitude of the amplitude of the vibration in the advancing direction excited at the vibrating body 605.

In the fifth exemplary embodiment, in addition to control of the speed and thrust, control of the upthrust vibration amplitude is performed. The amplitude of the current signal IA, which the amplitude detection unit 18 outputs, represents the vibration amplitude in the upthrust direction, and the upthrust vibration amplitude controller 30 compares an upthrust vibration amplitude command received from the command unit and the amplitude of the current signal IA and generates a frequency command signal in such a manner that the upthrust vibration amplitude command and the amplitude of the current signal IA coincide with each other. The alternating-current signal generation unit 15 sets frequencies of the alternating-current signals VA and VB according to the frequency command signal, so that the upthrust vibration amplitude is controlled.

When the upthrust vibration amplitude is controlled to be constant, the contact state between the contact body (rotor) 606 and the vibrating body 605 becomes stable, and it is possible to increase the stability of estimation of speed and thrust.

As described herein, the upthrust vibration amplitude controller 30 controls frequencies of the first alternating-current signal VA and the second alternating-current signal VB based on a value that is based on the amplitude of the first current signal IA, which the amplitude detection unit 18 outputs.

According to the first to fifth exemplary embodiments, each of the NN 20, the NN 39, and the NN 50 includes a plurality of input layers which is configured to receive, as inputs, at least a first input value and a second input value, a plurality of intermediate layers which is connected to the input layers, and an output layer which is connected to the plurality of intermediate layers.

The output layer outputs an estimated value of at least one of thrust occurring between the vibrating body 5 and the contact body 6, a relative speed between the vibrating body 5 and the contact body 6, a resonant frequency of the vibrating body 5, and a temperature of the vibrating body 5.

The first input value is a value that is based on at least one of a phase difference between the first alternating-current signal VA and the second alternating-current signal VB, frequencies of the first alternating-current signal VA and the second alternating-current signal VB, and an amplitude of the first alternating-current signal VA or the second alternating-current signal VB.

The second input value is a value that is based on at least one of a current that is based on the first alternating-current signal VA or the second alternating-current signal VB, a vibration occurring in the vibrating body 5, a voltage that is based on the first alternating-current signal VA or the second alternating-current signal VB, electric power that is based on the first alternating-current signal VA or the second alternating-current signal VB, and a phase difference between a voltage that is based on the first alternating-current signal VA or the second alternating-current signal VB and a current that is based on the first alternating-current signal VA or the second alternating-current signal VB.

The second input value is at least one of a measured value of a vibrational state in the vibrating body and a measured value corresponding to an admittance characteristic of the vibrating body. The second input value is a value that is based on at least one of an amplitude of the first current signal IA that is based on the first alternating-current signal VA, an amplitude of the second current signal IB that is based on the second alternating-current signal VB, an amplitude of a signal obtained by adding the first current signal IA and the second current signal IB, an amplitude of the first vibration detection signal SA that is based on the first electrode 3 of the piezoelectric element 2, an amplitude of the second vibration detection signal SB that is based on the second electrode 4 of the piezoelectric element 2, an amplitude of a signal obtained by adding the first vibration detection signal SA and the second vibration detection signal SB, an amplitude of the first voltage signal TA that is based on the first alternating-current signal VA, an amplitude of the second voltage signal TB that is based on the second alternating-current signal VB, an average value of the first electric power signal that is based on the first alternating-current signal VA, an average value of the second electric power signal that is based on the second alternating-current signal VB, a phase difference between a sum signal of the first voltage signal TA and the second voltage signal TB and a sum signal of the first current signal IA and the second current signal IB, and an amplitude of a signal obtained by subtracting the second current signal IB from the first current signal IA.

According to the first to fifth exemplary embodiments, the speed and thrust (torque) may be estimated of, for example, the vibration-type actuator 100 without use of speed and thrust detection sensors, to perform estimation in a wide frequency band.

The present disclosure can also be implemented by processing for supplying a program for implementing one or more functions of the above-described exemplary embodiments to a system or apparatus via a network or a storage medium and causing one or more processors included in a computer of the system or apparatus to read out and execute the program. Moreover, the present disclosure can also be implemented by a circuit which implements one or more functions of the above-described exemplary embodiments (for example, an application specific integrated circuit (ASIC)).

Each of the vibration-type drive devices 102, 412, 512, and 622 can be applied to an optical apparatus. The optical apparatus is, for example, a lens unit, which includes an optical element (lens) and each of the vibration-type drive devices 102, 412, 512, and 622, which drives the optical element. The lens unit is attachable to and detachable from a camera body.

Each of the vibration-type drive devices 102, 412, 512, and 622 may be applied to an image capturing apparatus. The image capturing apparatus is, for example, a camera body, which may include an image sensor and each of the vibration-type drive devices 102, 412, 512, and 622, drives the image sensor.

Each of the vibration-type drive devices 102, 412, 512, and 622 may be applied to an electronic apparatus. The electronic apparatus may include a member and each of the vibration-type drive devices 102, 412, 512, and 622 drives the member.

Each of the above-described exemplary embodiments represents an example for implementing the present disclosure, and should not be construed to limit the technical scope of the present disclosure. Thus, the present disclosure can be implemented in various forms without departing from the technical idea thereof or the principal features thereof.

Disclosures in the above-described exemplary embodiments include the following configurations.

### <Configuration 1>

A device for controlling an actuator including a vibrating body and a contact body, the vibrating body including an elastic body and an electro-mechanical energy converter, the contact body being in contact with the elastic body, the vibrating body and the contact body being configured to move relative to each other in response to vibration of the vibrating body, and the electro-mechanical energy converter includes a first electrode to which a first alternating-current (AC) voltage that is based on a first AC signal is applied and a second electrode to which a second AC voltage that is based on a second AC signal is applied, with the device including a neural network that includes:
a plurality of input layers configured to receive at least a first input value and a second input value;
a plurality of intermediate layers connected to the plurality of input layers; and
an output layer connected to the plurality of intermediate layers,
wherein the output layer outputs an estimated value of at least one of thrust between the vibrating body and the contact body, a speed of the vibrating body relative to the contact body, a resonant frequency of the vibrating body, and a temperature of the vibrating body,
wherein the first input value is based on at least one of a phase difference between the first AC signal and the second AC signal, frequencies of the first AC signal and the second AC signal, and an amplitude of the first AC signal or the second AC signal, and
wherein the second input value is at least one of a measured value of a vibrational state in the vibrating body and a measured value corresponding to an admittance of the vibrating body.

### <Configuration 2>

The device as set forth in Configuration 1, wherein the at least one of the measured value of the vibrational state of the vibrating body and the measured value corresponding to the admittance of the vibrating body is based on at least one of a current based on the first AC signal or the second AC signal, a vibration occurring in the vibrating body, a voltage based on the first AC signal or the second AC signal, electric power based on the first AC signal or the second AC signal, and a phase difference between a voltage based on the first AC signal or the second AC signal and a current based on the first AC signal or the second AC signal.

### <Configuration 3>

The device as set forth in Configuration 1 or 2, wherein the second input value is based on at least one of an amplitude of a first current signal based on the first AC signal, an amplitude of a second current signal based on the second AC signal, an amplitude of a signal obtained by adding the first current signal and the second current signal, an amplitude of a first vibration detection signal based on the first electrode of the electro-mechanical energy converter, an amplitude of a second vibration detection signal based on the second electrode of the electro-mechanical energy converter, an amplitude of a signal obtained by adding the first vibration detection signal and the second vibration detection signal, an amplitude of a first voltage signal that is based on the first AC signal, an amplitude of a second voltage signal that is based on the second AC signal, an average value of a first electric power signal based on the first AC signal, an average value of a second electric power signal that is based on the second AC signal, a phase difference between a sum signal of the first voltage signal and the second voltage signal and a sum signal of the first current signal and the second current signal, and an amplitude of a signal obtained by subtracting the second current signal from the first current signal.

### <Configuration 4>

The device as set forth in Configuration 3,
wherein the plurality of input layers includes:
a first input layer configured to receive an input that is based on a phase difference between the first AC signal and the second AC signal;
a second input layer configured to receive an input that is based on the amplitude of the first current signal;
a third input layer configured to receive an input that is based on the amplitude of the second current signal; and
a fourth input layer configured to receive an input that is based on the amplitude of the signal obtained by adding the first current signal and the second current signal, and
wherein the output layer includes:
a first output layer configured to output an estimated value of the thrust; and
a second output layer configured to output an estimated value of the relative speed.

### <Configuration 5>

The device as set forth in Configuration 3,
wherein the plurality of input layers includes:
a first input layer configured to receive an input that is based on a phase difference between the first AC signal and the second AC signal;
a second input layer configured to receive an input that is based on the amplitude of the first vibration detection signal;
a third input layer configured to receive an input that is based on the amplitude of the second vibration detection signal; and
a fourth input layer configured to receive a value that is based on the amplitude of the signal obtained by adding the first vibration detection signal and the second vibration detection signal, and
wherein the output layer includes:
a first output layer configured to output an estimated value of the thrust; and
a second output layer configured to output an estimated value of the relative speed.

### <Configuration 6>

The device as set forth in Configuration 3,
wherein the plurality of input layers includes:
a first input layer configured to receive an input that is based on a phase difference between the first AC signal and the second AC signal;
a second input layer configured to receive an input that is based on the amplitude of the first voltage signal;
a third input layer configured to receive an input that is based on the amplitude of the second voltage signal;
a fourth input layer configured to receive an input that is based on the amplitude of the first current signal;
a fifth input layer configured to receive an input that is based on the amplitude of the second current signal; and
a sixth input layer configured to receive an input that is based on the amplitude of the signal obtained by adding the first current signal and the second current signal, and
wherein the output layer includes:
a first output layer configured to output an estimated value of the thrust; and
a second output layer configured to output an estimated value of the relative speed.

### <Configuration 7>

The device as set forth in Configuration 3,
wherein the plurality of input layers includes:
a first input layer configured to receive an input that is based on a phase difference between the first AC signal and the second AC signal;
a second input layer configured to receive an input that is based on the average value of the first electric power signal;
a third input layer configured to receive an input that is based on the average value of the second electric power signal; and
a fourth input layer configured to receive an input that is based on the amplitude of the signal obtained by adding the first current signal and the second current signal, and
wherein the output layer includes:
a first output layer configured to output an estimated value of the thrust; and
a second output layer configured to output an estimated value of the relative speed.

### <Configuration 8>

The device as set forth in Configuration 3,
wherein the plurality of input layers includes:
a first input layer configured to receive an input that is based on the phase difference between the first AC signal and the second AC signal;
a second input layer configured to receive an input that is based on the phase difference between the sum signal of the first voltage signal and the second voltage signal and the sum signal of the first current signal and the second current signal;
a third input layer configured to receive an input that is based on the amplitude of the first current signal;
a fourth input layer configured to receive an input that is based on the amplitude of the second current signal; and
a fifth input layer configured to receive an input that is based on the amplitude of the signal obtained by adding the first current signal and the second current signal, and
wherein the output layer includes:
a first output layer configured to output an estimated value of the thrust; and
a second output layer configured to output an estimated value of the relative speed.

### <Configuration 9>

The device as set forth in Configuration 3,
wherein the plurality of input layers includes:
a first input layer configured to receive an input that is based on frequencies of the first AC signal and the second AC signal;
a second input layer configured to receive an input that is based on the phase difference between the first AC signal and the second AC signal;
a third input layer configured to receive an input that is based on the amplitude of the first current signal;
a fourth input layer configured to receive an input that is based on the amplitude of the second current signal; and
a fifth input layer configured to receive an input that is based on the amplitude of the signal obtained by adding the first current signal and the second current signal, and
wherein the output layer includes:
a first output layer configured to output an estimated value of the thrust;
a second output layer configured to output an estimated value of the relative speed; and
a third output layer configured to output an estimated value of the resonant frequency.

### <Configuration 10>

The device as set forth in Configuration 3,
wherein the plurality of input layers includes:
a first input layer configured to receive an input that is based on the frequencies of the first AC signal and the second AC signal;
a second input layer configured to receive an input that is based on the phase difference between the first AC signal and the second AC signal;
a third input layer configured to receive an input that is based on the amplitude of the first current signal;
a fourth input layer configured to receive an input that is based on the amplitude of the second current signal; and
a fifth input layer configured to receive an input that is based on the amplitude of the signal obtained by adding the first current signal and the second current signal, and
wherein the output layer includes:
a first output layer configured to output an estimated value of the thrust;
a second output layer configured to output an estimated value of the relative speed; and
a third output layer configured to output an estimated value of the temperature.

### <Configuration 11>

The device as set forth in Configuration 3,
wherein the plurality of input layers includes:
a first input layer configured to receive an input that is based on the amplitude of the second AC signal;
a second input layer configured to receive an input that is based on the amplitude of the signal obtained by adding the first current signal and the second current signal;
a third input layer configured to receive an input that is based on the amplitude of the signal obtained by subtracting the second current signal from the first current signal; and
a fourth input layer configured to receive an input that is based on the amplitude of the first current signal, and
wherein the output layer includes:
a first output layer configured to output an estimated value of the thrust; and
a second output layer configured to output an estimated value of the relative speed.

### <Configuration 12>

The device as set forth in Configuration 3,
wherein the plurality of input layers includes:
a first input layer configured to receive an input that is based on the phase difference between the first AC signal and the second AC signal;
a second input layer configured to receive an input that is based on the amplitude of the second current signal;
a third input layer configured to receive an input that is based on the amplitude of the first current signal; and
a fourth input layer configured to receive an input that is based on the amplitude of the signal obtained by adding the first current signal and the second current signal, and
wherein the output layer outputs an estimated value of the relative speed.

### <Configuration 13>

The device as set forth in any one of Configurations 4 to 10, wherein the device further includes a controller configured to control the phase difference between the first AC signal and the second AC signal based on the estimated value of the thrust and the estimated value of the relative speed.

### <Configuration 14>

The device as set forth in Configuration 10, wherein the device further includes a controller configured to control the phase difference between the first AC signal and the second AC signal based on the estimated value of the thrust, the estimated value of the relative speed, and the estimated value of the temperature.

### <Configuration 15>

The device as set forth in Configuration 9 or 10, wherein the device further includes a controller configured to control frequencies of the first AC signal and the second AC signal based on an amplitude of the signal obtained by adding the first current signal and the second current signal.

### <Configuration 16>

The device as set forth in Configuration 9, wherein the device further includes a controller configured to control frequencies of the first AC signal and the second AC signal based on an amplitude of a signal obtained by adding the first current signal the second current signal, and the estimated value of the resonant frequency.

### <Configuration 17>

The device as set forth in Configuration 11, wherein the device further includes a controller configured to control the amplitude of the second AC signal based on the estimated value of the thrust and the estimated value of the relative speed.

### <Configuration 18>

The device as set forth in Configuration 11 or 17, wherein the device further includes a controller configured to control frequencies of the first AC signal and the second AC signal based on a value that is based on an amplitude of a signal obtained by adding the first current signal and the second current signal.

### <Configuration 19>

The device as set forth in Configuration 12, wherein the device further includes a controller configured to control a phase difference between the first AC signal and the second AC signal based on the estimated value of the relative speed.

### <Configuration 20>

The device as set forth in any one of Configurations 1 to 19, wherein the plurality of input layers is configured to output a time-series plurality of input values to the plurality of intermediate layers.

### <Configuration 21>

The device as set forth in any one of Configurations 1 to 20, wherein each layer of the plurality of intermediate layers is configured as a recursive connection for returning an output to an input.

### <Configuration 22>

A vibration-type drive device including:
the actuator; and
the device as set forth in any one of Configurations 1 to 21.

### <Configuration 23>

An optical apparatus including:
an optical element; and
the vibration-type drive device as set forth in Configuration 22 configured to drive the optical element.

### <Configuration 24>

An image capturing apparatus including:
an image sensor; and
the vibration-type drive device as set forth in Configuration 22 configured to drive the image sensor.

### <Configuration 25>

An electronic apparatus including:
a member; and
the vibration-type drive device as set forth in Configuration 22 configured to drive the member.

According to an aspect of the present disclosure, the speed or thrust of a vibration-type actuator may be estimated without use of a speed or thrust detection sensor.

While the present disclosure has been made with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-004163 filed Jan. 15, 2024, which is hereby incorporated by reference herein in its entirety.

What is claimed is:

1. A device for controlling an actuator including a vibrating body and a contact body, the vibrating body including an elastic body and an electro-mechanical energy converter, the contact body being in contact with the elastic body, the vibrating body and the contact body being configured to move relative to each other in response to vibration of the vibrating body, and the electro-mechanical energy converter includes a first electrode to which a first alternating-current (AC) voltage based on a first AC signal is applied and a second electrode to which a second AC voltage based on a second AC signal is applied, the device comprising:
a neural network that includes:
a plurality of input layers configured to receive at least a first input value and a second input value;
a plurality of intermediate layers connected to the plurality of input layers; and
an output layer connected to the plurality of intermediate layers,
wherein the output layer outputs an estimated value of at least one of thrust between the vibrating body and the contact body, a speed of the vibrating body relative to the contact body, a resonant frequency of the vibrating body, and a temperature of the vibrating body,
wherein the first input value is based on at least one of a phase difference between the first AC signal and the second AC signal, frequencies of the first AC signal and the second AC signal, and an amplitude of the first AC signal or the second AC signal, and
wherein the second input value is at least one of a measured value of a vibrational state in the vibrating body and a measured value corresponding to an admittance of the vibrating body.

2. The device according to claim 1, wherein the at least one of the measured value of the vibrational state of the vibrating body and the measured value corresponding to the admittance of the vibrating body is based on at least one of a current based on the first AC signal or the second AC signal, a vibration occurring in the vibrating body, a voltage based on the first AC signal or the second AC signal, electric power based on the first AC signal or the second AC signal, and a phase difference between a voltage based on the first AC signal or the second AC signal and a current based on the first AC signal or the second AC signal.

3. The device according to claim 1, wherein the second input value is based on at least one of an amplitude of a first current signal based on the first AC signal, an amplitude of a second current signal based on the second AC signal, an amplitude of a signal obtained by adding the first current signal and the second current signal, an amplitude of a first vibration detection signal based on the first electrode of the electro-mechanical energy converter, an amplitude of a second vibration detection signal based on the second electrode of the electro-mechanical energy converter, an amplitude of a signal obtained by adding the first vibration detection signal and the second vibration detection signal, an amplitude of a first voltage signal based on the first AC signal, an amplitude of a second voltage signal based on the second AC signal, an average value of a first electric power signal based on the first AC signal, an average value of a second electric power signal based on the second AC signal, a phase difference between a sum signal of the first voltage signal and the second voltage signal and a sum signal of the first current signal and the second current signal, and an amplitude of a signal obtained by subtracting the second current signal from the first current signal.

4. The device according to claim 3,
wherein the plurality of input layers includes:
a first input layer configured to receive an input that is based on a phase difference between the first AC signal and the second AC signal;
a second input layer configured to receive an input that is based on the amplitude of the first current signal;
a third input layer configured to receive an input that is based on the amplitude of the second current signal; and
a fourth input layer configured to receive an input that is based on the amplitude of the signal obtained by adding the first current signal and the second current signal, and
wherein the output layer includes:
a first output layer configured to output an estimated value of the thrust; and
a second output layer configured to output an estimated value of the relative speed.

5. The device according to claim 3,
wherein the plurality of input layers includes:
a first input layer configured to receive an input that is based on a phase difference between the first AC signal and the second AC signal;
a second input layer configured to receive an input that is based on the amplitude of the first vibration detection signal;
a third input layer configured to receive an input that is based on the amplitude of the second vibration detection signal; and
a fourth input layer configured to receive an input that is based on the amplitude of the signal obtained by adding the first vibration detection signal and the second vibration detection signal, and
wherein the output layer includes:
a first output layer configured to output an estimated value of the thrust; and
a second output layer configured to output an estimated value of the relative speed.

6. The device according to claim 3,
wherein the plurality of input layers includes:
a first input layer configured to receive an input that is based on a phase difference between the first AC signal and the second AC signal;
a second input layer configured to receive an input that is based on the amplitude of the first voltage signal;
a third input layer configured to receive an input that is based on the amplitude of the second voltage signal;
a fourth input layer configured to receive an input that is based on the amplitude of the first current signal;
a fifth input layer configured to receive an input that is based on the amplitude of the second current signal; and
a sixth input layer configured to receive an input that is based on the amplitude of the signal obtained by adding the first current signal and the second current signal, and
wherein the output layer includes:
a first output layer configured to output an estimated value of the thrust; and
a second output layer configured to output an estimated value of the relative speed.

7. The device according to claim 3,
wherein the plurality of input layers includes:
a first input layer configured to receive an input that is based on a phase difference between the first AC signal and the second AC signal;
a second input layer configured to receive an input that is based on the average value of the first electric power signal;
a third input layer configured to receive an input that is based on the average value of the second electric power signal; and
a fourth input layer configured to receive an input that is based on the amplitude of the signal obtained by adding the first current signal and the second current signal, and
wherein the output layer includes:
a first output layer configured to output an estimated value of the thrust; and
a second output layer configured to output an estimated value of the relative speed.

8. The device according to claim 3,
wherein the plurality of input layers includes:
a first input layer configured to receive an input that is based on a phase difference between the first AC signal and the second AC signal;
a second input layer configured to receive an input that is based on the phase difference between the sum signal of the first voltage signal and the second voltage signal and the sum signal of the first current signal and the second current signal;
a third input layer configured to receive an input that is based on the amplitude of the first current signal;
a fourth input layer configured to receive an input that is based on the amplitude of the second current signal; and
a fifth input layer configured to receive an input that is based on the amplitude of the signal obtained by adding the first current signal and the second current signal, and
wherein the output layer includes:
a first output layer configured to output an estimated value of the thrust; and
a second output layer configured to output an estimated value of the relative speed.

9. The device according to claim 3,
wherein the plurality of input layers includes:
a first input layer configured to receive an input that is based on the frequencies of the first AC signal and the second AC signal;
a second input layer configured to receive an input that is based on the phase difference between the first AC signal and the second AC signal;
a third input layer configured to receive an input that is based on the amplitude of the first current signal;
a fourth input layer configured to receive an input that is based on the amplitude of the second current signal; and
a fifth input layer configured to receive an input that is based on the amplitude of the signal obtained by adding the first current signal and the second current signal, and
wherein the output layer includes:
a first output layer configured to output an estimated value of the thrust;
a second output layer configured to output an estimated value of the relative speed; and
a third output layer configured to output an estimated value of the resonant frequency.

10. The device according to claim 3,
wherein the plurality of input layers includes:
a first input layer configured to receive an input that is based on the frequencies of the first AC signal and the second AC signal;
a second input layer configured to receive an input that is based on the phase difference between the first AC signal and the second AC signal;
a third input layer configured to receive an input that is based on the amplitude of the first current signal;
a fourth input layer configured to receive an input that is based on the amplitude of the second current signal; and
a fifth input layer configured to receive an input that is based on the amplitude of the signal obtained by adding the first current signal and the second current signal, and
wherein the output layer includes:
a first output layer configured to output an estimated value of the thrust;
a second output layer configured to output an estimated value of the relative speed; and
a third output layer configured to output an estimated value of the temperature.

11. The device according to claim 3,
wherein the plurality of input layers includes:
a first input layer configured to receive an input that is based on the amplitude of the second AC signal;
a second input layer configured to receive an input that is based on the amplitude of the signal obtained by adding the first current signal and the second current signal;
a third input layer configured to receive an input that is based on the amplitude of the signal obtained by subtracting the second current signal from the first current signal; and
a fourth input layer configured to receive an input that is based on the amplitude of the first current signal, and
wherein the output layer includes:
a first output layer configured to output an estimated value of the thrust; and
a second output layer configured to output an estimated value of the relative speed.

12. The device according to claim 3,
wherein the plurality of input layers includes:
a first input layer configured to receive an input that is based on the phase difference between the first AC signal and the second AC signal;
a second input layer configured to receive an input that is based on the amplitude of the second current signal;
a third input layer configured to receive an input that is based on the amplitude of the first current signal; and
a fourth input layer configured to receive an input that is based on the amplitude of the signal obtained by adding the first current signal and the second current signal, and
wherein the output layer outputs an estimated value of the relative speed.

13. The device according to claim 4, further comprising a controller configured to control the phase difference between the first AC signal and the second AC signal based on the estimated value of the thrust and the estimated value of the relative speed.

14. The device according to claim 10, further comprising a controller configured to control the phase difference between the first AC signal and the second AC signal based on the estimated value of the thrust, the estimated value of the relative speed, and the estimated value of the temperature.

15. The device according to claim 9, further comprising a controller configured to control frequencies of the first AC signal and the second AC signal based on an amplitude of the signal obtained by adding the first current signal and the second current signal.

16. The device according to claim 9, further comprising a controller configured to control frequencies of the first AC signal and the second AC signal based on an amplitude of a signal obtained by adding the first current signal, the second current signal, and the estimated value of the resonant frequency.

17. The device according to claim 11, further comprising a controller configured to control the amplitude of the second AC signal based on the estimated value of the thrust and the estimated value of the relative speed.

18. The device according to claim 11, further comprising a controller configured to control frequencies of the first AC signal and the second AC signal based on an amplitude of a signal obtained by adding the first current signal and the second current signal.

19. The device according to claim 12, further comprising a controller configured to control a phase difference between the first AC signal and the second AC signal based on the estimated value of the relative speed.

20. The device according to claim 1, wherein the plurality of input layers is configured to output a time-series plurality of input values to the plurality of intermediate layers.

21. The device according to claim 1, wherein each layer of the plurality of intermediate layers is configured as a recursive connection for returning an output to an input.

22. A vibration-type drive device comprising:
the actuator; and
the device according to claim 1.

23. An optical apparatus comprising:
an optical element; and
the vibration-type drive device according to claim 22 configured to drive the optical element.

24. An image capturing apparatus comprising:
an image sensor; and
the vibration-type drive device according to claim 22 configured to drive the image sensor.

25. An electronic apparatus comprising:
a member; and
the vibration-type drive device according to claim 22 configured to drive the member.
